(19) United States
(12) Patent Application Publication
(10) Pub. No.: US 2025/0039578 A1
(43) Pub. Date: Jan. 30, 2025

(54) IMAGING DEVICE AND SEMICONDUCTOR MEMORY

(71) Applicant: SONY SEMICONDUCTOR SOLUTIONS CORPORATION, KANAGAWA (JP)

(72) Inventor: MASAKI SAKAKIBARA, TOKYO (JP)

(21) Appl. No.: 18/708,233

(22) PCT Filed: Nov. 9, 2022
(86) PCT No.: PCT/JP2022/041637

§ 371 Date: May 8, 2024

(30) Foreign Application Priority Data
Nov. 16, 2021 (JP) 2021-186539

(51) Int. Cl. H04N 25/772; H04N 25/768

(52) U.S. Cl. CPC H04N 25/772; H04N 25/768

(57) ABSTRACT

A storage unit included in each of pixels is miniaturized to increase the number of pixels per unit area.

An imaging device includes a storage unit that stores a time code including a plurality of bits and corresponding to a pixel signal. The storage unit has a first inverter and a second inverter connected in a ring shape for each of the bits. The first inverter includes a first transistor that is of P-type and has a source connected to a first reference voltage node and a gate connected to an output node of the second inverter, a second transistor that is of P-type and has a source connected to a drain of the first transistor, a gate to which an inversion signal of a first control signal is input, and a drain connected to an output node of the first inverter, a third transistor that is of N-type and has a drain connected to the drain of the second transistor and a gate to which the first control signal is input, and a fourth transistor that is of N-type and has a drain connected to a source of the third transistor and a gate connected to a source connected to a second reference voltage node.

### TECHNICAL FIELD

The present disclosure relates to an imaging device and a semiconductor memory.

### BACKGROUND ART

A pixel AD converter (hereinafter referred to as an ADC) type imaging device conventionally known has an ADC which achieves, for each pixel, analog-digital conversion (hereinafter referred to as AD conversion) of a pixel signal photoelectrically converted for each pixel (see PTL 1). A typical pixel ADC type imaging device includes an ADC and a storage unit which stores AD-converted image data for each pixel.

### CITATION LIST

### Patent Literature

### [PTL 1]

PCT Patent Publication No. WO16/136448

### SUMMARY

### Technical Problem

For example, the storage unit provided for each pixel has a SRAM (Static Random Access Memory). The SRAM includes a pair of bit lines, a plurality of PMOS transistors, and a plurality of NMOS transistors. Drive capability of the PMOS transistors is different from drive capability of the NMOS transistors. Accordingly, drive capability adjustment such as a size increase of the PMOS transistors is required. The SRAM therefore does not necessarily have a symmetric layout. In this case, the layout of the SRAM is difficult to optimize, and a circuit area of the SRAM is likely to increase.

For solving the problem described above, the present disclosure provides an imaging device and a semiconductor memory each capable of increasing the number of pixels per unit area by miniaturizing a storage unit provided in each pixel.

### Solution to Problem

For solving the problem described above, according to the present disclosure, there is provided an imaging device including a pixel array unit that has a plurality of pixels, a time code generation unit that generates a time code changing with time, a reference signal generation unit that generates a reference signal that has a voltage level changing with time, and an AD converter that achieves analog-digital conversion of a pixel signal by comparison between the pixel signal and the reference signal. The AD converter has a storage unit that stores the time code including a plurality of bits and corresponding to the pixel signal by comparison between the pixel signal and the reference signal. The storage unit has, for each of the plurality of bits, a first inverter that switches whether or not to perform an inversion output operation of an input signal according to a first control signal, and a second inverter that has an input node connected to an output node of the first inverter and an output node connected to an input node of the first inverter. The first inverter has a first transistor that is of P-type and has a source connected to a first reference voltage node and a gate connected to the output node of the second inverter, a second transistor that is of P-type and has a source connected to a drain of the first transistor, a gate to which an inversion signal of the first control signal is input, and a drain connected to the output node of the first inverter, a third transistor that is of N-type and has a drain connected to the drain of the second transistor and the output node of the first inverter and a gate to which the first control signal is input, and a fourth transistor that is of N-type and has a drain connected to a source of the third transistor, a source connected to a second reference voltage node, and a gate connected to the output node of the second inverter.

The second inverter may have a fifth transistor that is of P-type and has a source connected to the first reference voltage node, a drain connected to the gate of the first transistor and the gate of the fourth transistor, and a gate connected to the output node of the first inverter, and a sixth transistor that is of N-type and has a drain connected to the drain of the fifth transistor, a source connected to the second reference voltage node, and a gate connected to the output node of the first inverter.

Bit data corresponding to a time code associated with the pixel signal may be written to the storage unit via one digital signal bit line for each bit, and the bit data that corresponds to the time code and that is read from the storage unit may be output to the one digital signal bit line.

The storage unit may have, for each of the plurality of bits, a transfer gate connected between the output node of the first inverter and the digital signal bit line, the transfer gate may have a seventh transistor of N-type and an eighth transistor of P-type, the seventh transistor and the eighth transistor being connected in parallel between the output node of the first inverter and the digital signal bit line, and a second control signal for controlling opening and closing of the transfer gate may be input to each of gates of the seventh transistor and the eighth transistor.

The time code associated with the pixel signal may be stored in the storage unit for each bit via the digital signal bit line and the transfer gate, and the time code stored in the storage unit may be read via the digital signal bit line and the transfer gate.

The storage unit may have a first storage unit that stores the time code associated with the pixel signal at a reset level and a second storage unit that stores the time codes associated with the pixel signals corresponding to intensity levels of each light entering the plurality of pixels, and the first storage unit and the second storage unit may share the digital signal bit line for each of the plurality of bits.

Each of the first storage unit and the second storage unit may have the first inverter, the second inverter, and the transfer gate, and the same digital signal bit line may be connected to the respective transfer gates of the first storage unit and the second storage unit included in the same bit.

A plurality of the storage units corresponding to a plurality of adjoining pixels may read and write the bit data corresponding to the time code via the same digital signal bit line for each bit.

The imaging device may further include a first diffusion layer and a second diffusion layer each extending in a first direction and disposed away from each other in a second direction crossing the first direction, a first gate layer, a second gate layer, a third gate layer, a fourth gate layer, a fifth gate layer, and a sixth gate layer disposed on the first diffusion layer and the second diffusion layer, each extending in the second direction, and disposed away from each other in the first direction, a first wiring layer disposed on the first gate layer via a first contact, a second wiring layer disposed on the second gate layer via a second contact, a third wiring layer disposed on the third gate layer via a third contact, a fourth wiring layer disposed on the fourth gate layer via a fourth contact, a fifth wiring layer disposed on the fifth gate layer via a fifth contact, a sixth wiring layer disposed on the sixth gate layer via a sixth contact, a first diffusion region, a second diffusion region, a third diffusion region, a fourth diffusion region, and a fifth diffusion region disposed away from each other inside the first diffusion layer, a sixth diffusion region, a seventh diffusion region, an eighth diffusion region, a ninth diffusion region, and a tenth diffusion region disposed away from each other inside the second diffusion layer, a seventh wiring layer disposed on the second diffusion region via a seventh contact and conductively connected to the first reference voltage node, an eighth wiring layer disposed on the seventh diffusion region via an eighth contact and conductively connected to the second reference voltage node, a ninth wiring layer disposed on the first diffusion region via a ninth contact and disposed on the sixth diffusion region via a tenth contact, a tenth wiring layer disposed on the fourth diffusion region via an eleventh contact and disposed on the ninth diffusion region via a twelfth contact, and an eleventh wiring layer disposed on the fifth diffusion region via a thirteenth contact and disposed on the tenth diffusion region via a fourteenth contact. The first gate layer may be connected to the gate of the fifth transistor and the gate of the sixth transistor, the second gate layer may be connected to the gate of the first transistor and the gate of the fourth transistor, the third gate layer may be connected to the gate of the third transistor, the fourth gate layer may be connected to the gate of the second transistor, the fifth gate layer may be connected to the gate of the seventh transistor, and the sixth gate layer may be connected to the gate of the eighth transistor. The first diffusion region may include a source region of the fifth transistor, the second diffusion region may include a drain region of the fifth transistor and a source region of the first transistor, the third diffusion region may include a drain region of the first transistor and a source region of the second transistor, the fourth diffusion region may include a drain region of the second transistor and a drain region of the eighth transistor, the fifth diffusion region may include a source region of the eighth transistor, the sixth diffusion region may include a drain region of the sixth transistor, the seventh diffusion region may include a source region of the sixth transistor and a source region of the fourth transistor, the eighth diffusion region may include a drain region of the fourth transistor and a source region of the third transistor, the ninth diffusion region may include a drain region of the third transistor and a source region of the seventh transistor, and the tenth diffusion region may include a drain region of the seventh transistor.

Each of the first transistor, the second transistor, the fifth transistor, and the eighth transistor disposed on the first diffusion layer may be of a first conductivity type, and each of the third transistor, the fourth transistor, the sixth transistor, and the seventh transistor disposed on the second diffusion layer may be of a second conductivity type.

Four diffusion layers that include the first diffusion layer and the second diffusion layer may be so disposed as to extend in the first direction, the four diffusion layers may be disposed away from each other in the second direction, and transistor groups may be disposed on the four diffusion layers in an order of a first conductivity type, a second conductivity type, the second conductivity type, and the first conductivity type in the second direction.

The third gate layer may be a partial conductive layer that is one of two divisions of a first conductive layer extending in the second direction, and the fourth gate layer may be the other partial conductive layer of the two divisions.

The fifth gate layer may be a partial conductive layer that is one of two divisions of a second conductive layer CL2 extending in the second direction, and the sixth gate layer may be the other partial conductive layer of the two divisions.

The first to sixth gate layers, the first to eleventh wiring layers, and the first to tenth diffusion regions of two bits disposed adjacently to each other in the first direction within the storage unit may be line-symmetrically disposed with respect to a boundary line extending in the second direction.

The first to sixth gate layers, the first to eleventh wiring layers, and the first to tenth diffusion regions of two bits disposed adjacently to each other in the second direction within the storage unit may be line-symmetrically disposed with respect to a boundary line extending in the first direction.

The first to sixth gate layers, the first to eleventh wiring layers, and the first to tenth diffusion regions of two bits disposed adjacently to each other in each of the first direction and the second direction within the storage unit may be line-symmetrically disposed with respect to each of a first boundary line extending in the first direction and a second boundary line extending in the second direction.

The imaging device may further include a pre-charge circuit that pre-charges the digital signal bit line to a predetermined potential before writing of the time code to the storage unit.

The digital signal bit line may perform writing of the time code to the storage unit and reading of the time code from the storage unit by time division.

According to the present disclosure, there is provided a semiconductor memory including a storage unit that includes a plurality of bits. The storage unit has, for each of the plurality of bits, a first inverter that switches whether or not to perform an inversion output operation of an input signal according to a first control signal, a second inverter connected to an input node and an output node of the first inverter, and a transfer gate connected between the output node of the first inverter and a digital signal bit line. The first inverter has a first transistor that is of P-type and has a source connected to a first reference voltage node and a gate connected to an output node of the second inverter, a second transistor that is of P-type and has a source connected to a drain of the first transistor, a gate to which an inversion signal of the first control signal is input, and a drain connected to an output node, a third transistor that is of N-type and has a drain connected to the drain of the second transistor and the output node and a gate to which the first control signal is input, and a fourth transistor that is of N-type and has a drain connected to a source of the third transistor, a source connected to a second reference voltage node, and a gate connected to the output node of the second inverter. The second inverter has a fifth transistor that has a source connected to the first reference voltage node, a drain connected to the gate of the first transistor and the gate of the fourth transistor, and a gate connected to the drain of the second transistor and the drain of the third transistor, and a sixth transistor that has a drain connected to the gate of the first transistor and the gate of the fourth transistor, a source connected to the second reference voltage node, and a gate connected to the drain of the second transistor and the drain of the third transistor. The transfer gate has a seventh transistor of N-type and an eighth transistor of P-type connected in parallel between the output node of the first inverter and the digital signal bit line. A second control signal for controlling opening and closing of the transfer gate is input to each of gates of the seventh transistor and the eighth transistor.

### BRIEF DESCRIPTION OF DRAWINGS

FIG. 1 is a diagram depicting a schematic configuration of a solid-state imaging device according to the present disclosure.

FIG. 2 is a block diagram depicting a detailed configuration example of a pixel.

FIG. 3 is a block diagram depicting a detailed configuration example of a comparison circuit.

FIG. 4 is a diagram illustrating transitions of respective signals during operation of the comparison circuit.

FIG. 5 is a diagram explaining a detailed configuration of a pixel circuit.

FIG. 6 is a timing chart explaining an operation of a pixel.

FIG. 7 is a circuit diagram depicting specific configurations of a time code transfer unit and a data storage unit.

FIG. 8 is a circuit diagram depicting internal configurations of P-phase bit storage units and D-phase bit storage units.

FIG. 9 is a diagram depicting an example where local bit lines are shared by a plurality of latch storage units included in a plurality of pixels in a cluster.

FIG. 10 is a specific circuit diagram of the P-phase bit storage unit and the D-phase bit storage unit.

FIG. 11 is a diagram depicting an example of a layout for arranging the circuit depicted in FIG. 10.

FIG. 12 is a diagram depicting a layout for arranging a plurality of bits.

FIG. 13 is a diagram schematically depicting arrangement directions of four bits depicted in FIG. 12.

FIG. 14 is a diagram depicting an example of an imaging device formed by laminating a pixel substrate and a logic substrate.

FIG. 15 is a block diagram depicting an example of schematic configuration of a vehicle control system.

FIG. 16 is a diagram of assistance in explaining an example of installation positions of an outside-vehicle information detecting section and an imaging section.

### DESCRIPTION OF EMBODIMENT

An imaging device and a semiconductor memory according to an embodiment will hereinafter be described with reference to the drawings. While chiefly described below will be main constituent parts of the imaging device and the semiconductor memory, each of the imaging device and the semiconductor memory may further include constituent parts and functions not depicted nor explained. The following description does not exclude these constituent parts and functions not depicted nor explained.

### Schematic Configuration Example of Imaging Device

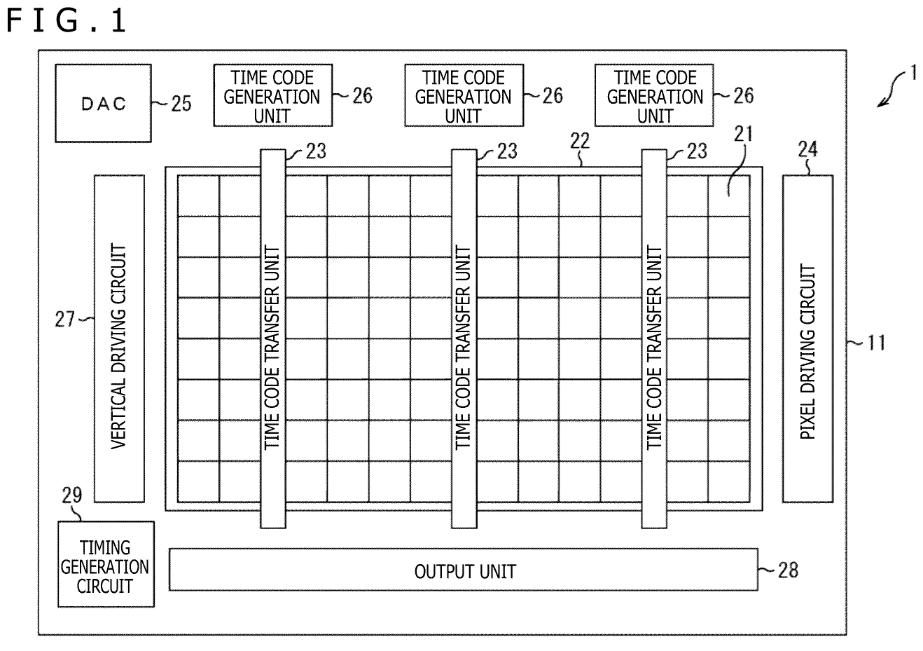

FIG. 1 depicts a schematic configuration of an imaging device 1 according to the present disclosure. Chiefly explained below will be the imaging device 1 formed on a semiconductor substrate. The imaging device 1 of this type is also called the solid-state imaging device 1 in some cases but will simply be referred to as the imaging device 1 hereinafter.

The imaging device 1 in FIG. 1 includes a semiconductor substrate 11 using, for example, silicon (Si) as a semiconductor, and a pixel array unit 22 including pixels 21 arranged in a form of a two-dimensional array. The pixel array unit 22 includes time code transfer units 23 for transferring time codes generated by time code generation units 26 to the respective pixels 21. In addition, a pixel driving circuit 24, a DAC (D/A converter) 25, the time code generation units 26, a vertical driving circuit 27, an output unit 28, and a timing generation circuit 29 are further formed around the pixel array unit 22 on the semiconductor substrate 11.

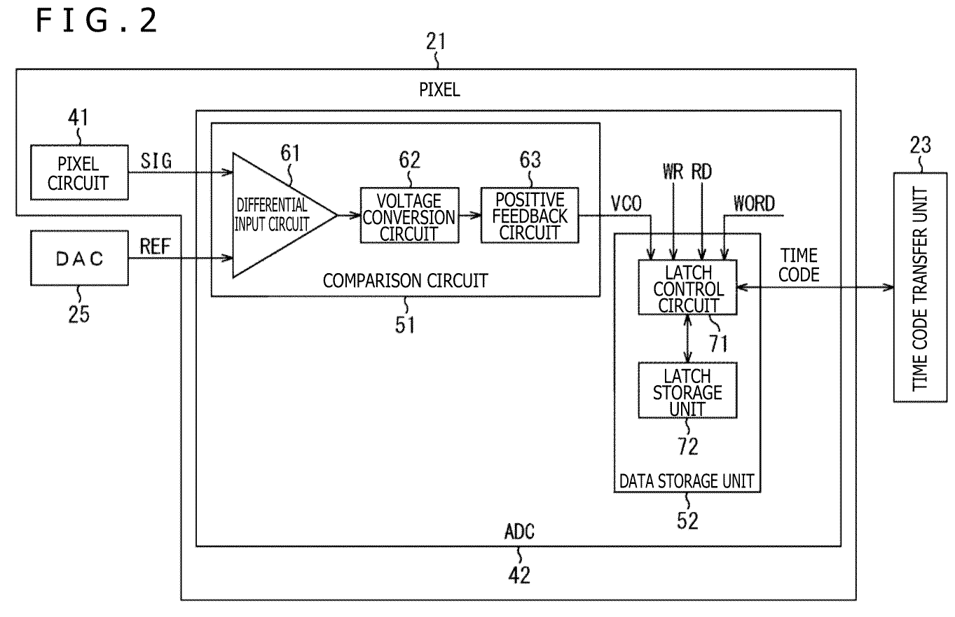

FIG. 2 is a block diagram depicting a configuration of each of the pixels 21 arranged in the pixel array unit 22 in the two-dimensional array form. As depicted in FIG. 2, each of the pixels 21 has a pixel circuit 41 and an ADC 42. Each of the pixels 21 generates a charge signal corresponding to a light amount received by a light receiving element (e.g., photodiode) provided within the pixel, converts the generated charge signal into a digital pixel signal, and outputs the digital pixel signal.

The pixel driving circuit 24 in FIG. 1 drives the pixel circuit 41 (FIG. 2) provided in each of the pixels 21. The DAC 25 generates a reference signal (reference voltage signal) REF, which is a slope signal whose level (voltage) monotonously decreases with an elapse of time, and supplies the generated reference signal REF to each of the pixels 21. Each of the time code generation units 26 generates a time code used by each of the pixels 21 at the time of conversion from an analog pixel signal SIG into a digital pixel signal (AD conversion) and supplies the generated time code to the corresponding time code transfer unit 23. The pixel array unit 22 has a plurality of the time code generation units 26. The same number of the time code transfer units 23 as the number of the time code generation units 26 are provided within the pixel array unit 22. Specifically, the time code generation units 26 and the time code transfer units 23 for transferring time codes generated by the time code generation units 26 are provided with one-to-one correspondence.

The vertical driving circuit 27 performs control for causing the output unit 28 to output the digital pixel signal generated in each of the pixels 21 via the corresponding time code transfer unit 23 in a predetermined order according to a timing signal supplied from the timing generation circuit 29. The digital pixel signal output from each of the pixels 21 is thus output from the output unit 28 to the outside of the imaging device 1. The output unit 28 performs predetermined digital signal processes, such as a black level correction process for correcting a black level and a CDS (Correlated Double Sampling) process, as necessary, and then outputs the processed signal to the outside. As described above, the output unit 28 has built-in functions for performing various arithmetic processes and signal processes.

The timing generation circuit 29 has a timing generator for generating various types of timing signals and other components and supplies various types of generated timing signals to the pixel driving circuit 24, the DAC 25, the vertical driving circuit 27, and the like.

The imaging device 1 is configured as described above. While described with reference to FIG. 1 is a case where all circuits constituting the imaging device 1 are formed on the one semiconductor substrate 11, such a configuration which has circuits constituting the imaging device 1 and disposed separately on a plurality of semiconductor substrates may be adopted as will be described below.

### Detailed Configuration Example of Pixel

As depicted in FIG. 2, each of the pixels 21 has the pixel circuit 41 and the ADC (AD converter) 42. Accordingly, the imaging device 1 in the present embodiment is the pixel ADC type imaging device 1 which includes pixels each having the ADC 42.

The pixel circuit 41 outputs a charge signal corresponding to a received light amount to the ADC 42 as the analog pixel signal SIG. The ADC 42 converts the analog pixel signal SIG supplied from the pixel circuit 41 into a digital pixel signal. The ADC 42 has a comparison circuit 51 and a data storage unit 52.

The comparison circuit 51 compares the reference signal REF supplied from the DAC 25 with the pixel signal SIG and outputs an output signal VCO as a comparison result signal indicating a comparison result. The comparison circuit 51 inverts a potential of the output signal VCO when the reference signal REF and the pixel signal SIG are equalized (have the same voltage).

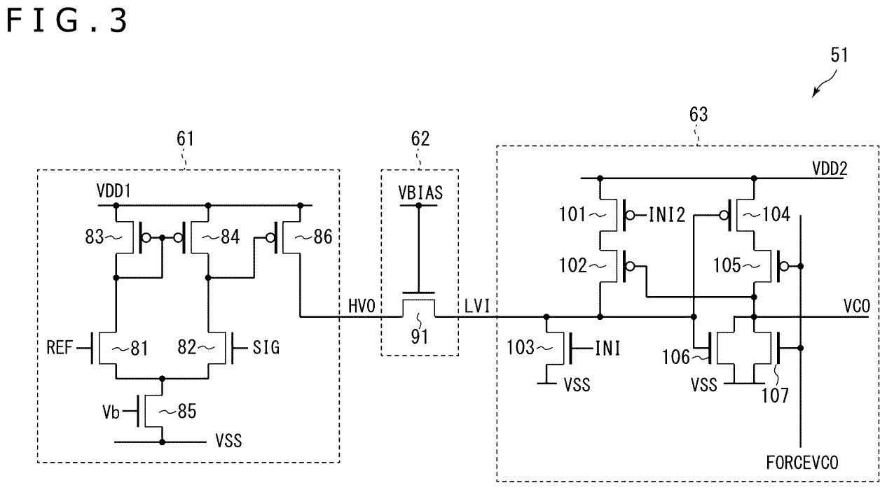

The comparison circuit 51 has a differential input circuit 61, a voltage conversion circuit 62, and a positive feedback circuit (PFB: positive feedback) 63. A detailed configuration of the comparison circuit 51 will be described below with reference to FIG. 3.

The data storage unit 52 receives input of the output signal VCO from the comparison circuit 51, and also receives a WR signal indicating a write operation of a pixel signal (hereinafter also referred to as a write control signal WR), an RD signal indicating a read operation of a pixel signal (hereinafter also referred to as a read control signal RD), and a WORD signal for controlling read timing of the pixel 21 during a read operation of a pixel signal, each supplied from the vertical driving circuit 27. The data storage unit 52 further receives a time code generated by the time code generation unit 26 and supplied via the time code transfer unit 23.

The data storage unit 52 has a latch control circuit (storage control unit) 71 for controlling the time code write operation and the time code read operation on the basis of the WR signal and the RD signal, and a latch storage unit 72 for storing a time code.

For the time code write operation, during input of the high-level output signal VCO from the comparison circuit 51, the latch control circuit 71 causes the latch storage unit 72 to store a time code supplied from the time code transfer unit 23 and updated for each unit time. Thereafter, when the output signal VCO supplied from the comparison circuit 51 is inverted to a low-level signal in response to equalization (of voltage) between the reference signal REF and the pixel signal SIG, the latch control circuit 71 stops writing (updating) of the supplied time code and causes the latch storage unit 72 to retain the latest time code stored in the latch storage unit 72. The time code retained in the latch storage unit 72 indicates a time when the pixel signal SIG and the reference signal REF are equalized, and corresponds to data, i.e., a digitalized light amount value, indicating that the pixel signal SIG has a reference voltage at that time.

After sweeping of the reference signal REF is completed and the time codes are retained in the latch storage units 72 of all the pixels 21 included in the pixel array unit 22, the operation of each of the pixels 21 is updated from the write operation to the read operation.

For the time code read operation, the latch control circuit 71 outputs the time code (digital pixel signal) stored in the latch storage unit 72 to the time code transfer unit 23 at the read timing of the corresponding pixel 21 on the basis of the read control signal RD and the WORD signal controlling the read timing. The time code transfer unit 23 sequentially transfers the supplied time code in a read direction (column direction (vertical direction) toward the output unit 28 in FIG. 1) to supply the time code to the output unit 28. In some cases, the time code transfer unit 23 transfers time codes for each cluster which includes a plurality of pixels arranged adjacently to each other.

### Configuration Example of Comparison Circuit

FIG. 3 is a circuit diagram depicting detailed configurations of the differential input circuit 61, the voltage conversion circuit 62, and the positive feedback circuit 63 included in the comparison circuit 51 depicted in FIG. 2.

The differential input circuit 61 compares the pixel signal SIG output from the pixel circuit 41 included in each of the pixels 21 with the reference signal REF output from the DAC 25, and outputs a predetermined signal (current) when the pixel signal SIG is higher than the reference signal REF.

The differential input circuit 61 has transistors 81 and 82 constituting a differential pair, transistors 83 and 84 constituting a current mirror, a transistor 85 as a constant-current source for supplying current IB corresponding to input bias current Vb, and a transistor 86 for outputting an output signal HVO of the differential input circuit 61.

Each of the transistors 81, 82, and 85 is an NMOS (Negative Channel MOS) transistor, while each of the transistors 83, 84, and 86 is a PMOS (Positive Channel MOS) transistor.

The reference signal REF output from the DAC 25 is input to a gate of the transistor 81 included in the transistors 81 and 82 constituting a differential pair, while the pixel signal SIG output from the pixel circuit 41 included in the pixel 21 is input to a gate of the transistor 82. Sources of the transistors 81 and 82 are connected to a drain of the transistor 85, while a source of the transistor 85 is connected to a predetermined voltage VSS (VSS<VDD2<VDD1).

A drain of the transistor 81 is connected to gates of the transistors 83 and 84 constituting the current mirror circuit and to a drain of the transistor 83, while a drain of the transistor 82 is connected to a drain of the transistor 84 and a gate of the transistor 86. Sources of the transistors 83, 84, and 86 are connected to a first power source voltage VDD1.

For example, the voltage conversion circuit 62 has an NMOS-type transistor 91. A drain of the transistor 91 is connected to a drain of the transistor 86 of the differential input circuit 61. A source of the transistor 91 is connected to predetermined connection points within the positive feedback circuit 63. A gate of the transistor 91 is connected to a node of a bias voltage VBIAS.

The transistors 81 to 86 constituting the differential input circuit 61 form a circuit operating at a high voltage not exceeding the first power source voltage VDD1, while the positive feedback circuit 63 is a circuit operating at a second power source voltage VDD2 lower than the first power source voltage VDD1. The voltage conversion circuit 62 converts the output signal HVO input from the differential input circuit 61 into a low-voltage signal (conversion signal) LVI at the level of which the positive feedback circuit 63 is operable, and supplies the signal LVI to the positive feedback circuit 63.

The vias voltage VBIAS is only required to be a voltage allowing conversion into a voltage not causing breakdown of the respective transistors 101 to 105 of the positive feedback circuit 63 operating at a low voltage. For example, the bias voltage VBIAS can be equalized with the second power source voltage VDD2 of the positive feedback circuit 63 (VBIAS=VDD2). A similar voltage conversion effect is achievable in the condition of VBIAS=VDD2.

The positive feedback circuit 63 outputs a comparison result signal which is inverted when the pixel signal SIG is higher than the reference signal REF, on the basis of the conversion signal LVI obtained by conversion of the output signal HVO from the differential input circuit 61 into the signal corresponding to the second power source voltage VDD2. Moreover, the positive feedback circuit 63 increases a transition speed at the time of inversion of the output signal VCO output as the comparison result signal.

The positive feedback circuit 63 has the five transistors 101 to 107. Each of the transistors 101, 102, 104, and 105 herein is a PMOS transistor, while each of the transistors 103, 106, and 107 is an NMOS transistor.

The source of the transistor 91 which is an output end of the voltage conversion circuit 62 is connected to drains of the transistors 102 and 103 and gates of the transistors 104 and 106. Sources of the transistors 101 and 104 are connected to the second power source voltage VDD2. A drain of the transistor 101 is connected to a source of the transistor 102. A gate of the transistor 102 is connected to drains of the transistors 105 and 107 each of which is also an output end of the positive feedback circuit 63. Sources of the transistors 103, 106, and 107 are connected to the predetermined voltage VSS. An initializing signal INI2 is supplied to a gate of the transistor 101, while an initializing signal INI is supplied to a gate of the transistor 103.

A FORCEVCO signal is input to gates of the transistors 105 and 107. When the FORCEVCO signal is a high-level signal, the transistor 107 is turned on. In this case, the VCO signal is a low-level signal.

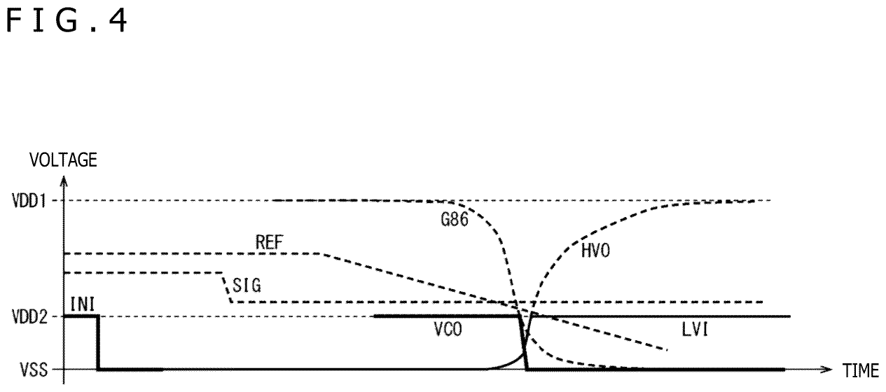

An operation performed by the comparison circuit 51 configured as above will be touched upon. FIG. 4 illustrates transitions of the respective signals during operation of the comparison circuit 51. Note that “G86” in FIG. 4 represents a gate potential of the transistor 86.

Initially, the reference signal REF is set to a voltage higher than those of the pixel signals SIG of all the pixels 21, and both the initializing signal INI and the not-illustrated initializing signal INI2 are brought into a high level to initialize the comparison circuit 51.

More specifically, the reference signal REF is applied to the gate of the transistor 81, and the pixel signal SIG is applied to the gate of the transistor 82 in FIG. 3. When the voltage of the reference signal REF is higher than the voltage of the pixel signal SIG, most of current which flows between the drain and the source of the transistor 85 constituting a current source flows through the transistor 81 to the diode-connected transistor 83. Channel resistance of the transistor 84 having the gate shared with the transistor 83 is sufficiently lowered. In this case, the transistor 86 maintains the gate substantially at the first power source voltage VDD1 level and is cut off. Accordingly, even if the transistor 91 of the voltage conversion circuit 62 is in a conductive state, the positive feedback circuit 63 as a charging circuit does not charge the conversion signal LVI. Meanwhile, a high-level signal is supplied to the positive feedback circuit 63 as the initializing signal INI. Accordingly, the transistor 103 is brought into a conductive state, and the positive feedback circuit 63 discharges the conversion signal LVI. At this time, the initializing signal INI2 is a high-level signal, and the transistor 101 is cut off. Accordingly, the positive feedback circuit 63 does not charge the conversion signal LVI via the transistor 102, as in the case described above. As a result, the conversion signal LVI is discharged to the predetermined voltage VSS level, and the positive feedback circuit 63 outputs the high-level output signal VCO via the transistors 104 and 106 constituting an inverter to initialize the comparison circuit 51. After initialization, both of the initializing signals INI and INI2 are brought into a low level. As a result, the transistor 103 is turned off, and sweeping of the reference signal REF is started.

In a period when the reference signal REF has a higher voltage than the pixel signal SIG, the transistor 86 is turned off and thus is cut off, and the output signal VCO becomes a high-level signal. Accordingly, the transistor 102 is also turned off and cut off. The transistor 103 is also cut off because the initializing signal INI is at the low level. The conversion signal LVI maintains the predetermined voltage VSS continuously in a high-impedance state, and the high-level output signal VCO is output.

When the reference signal REF becomes lower than the pixel signal SIG, the output current from the transistor 85 as the current source stops flowing in the transistor 81. As a result, each of the gate potentials of the transistors 83 and 84 increases, and the channel resistance of the transistor 84 increases. In this condition, the current entering via the transistor 82 causes a voltage drop and lowers the gate potential of the transistor 86. As a result, the transistor 91 is brought into a conductive state. The output signal HVO output from the transistor 86 is converted into the conversion signal LVI by the transistor 91 of the voltage conversion circuit 62 and supplied to the positive feedback circuit 63. The positive feedback circuit 63 as a charging circuit charges the conversion signal LVI to increase the potential from the low voltage VSS toward the second power source voltage VDD2.

Thereafter, when the voltage of the conversion signal LVI exceeds a threshold voltage of the inverter having the transistors 104 and 106, the output signal VCO becomes a low-level signal. As a result, the transistor 102 is brought into a conductive state. The transistor 101 to which the low-level initializing signal INI is applied is also in a conductive state. Accordingly, the positive feedback circuit 63 rapidly charges the conversion signal LVI via the transistors 101 and 102 to instantly raise the potential to the second power source voltage VDD2.

The bias voltage VBIAS is applied to the gate of the transistor 91 of the voltage conversion circuit 62. Accordingly, when the voltage of the conversion signal LVI reaches a voltage value lower than the bias voltage VBIAS by a threshold of the transistor, the transistor 91 is cut off. Even if the transistor 86 is kept in the conductive state, the conversion signal LVI is not charged any further. Accordingly, the voltage conversion circuit 62 also functions as a voltage clamp circuit.

Charging the conversion signal LVI by conduction of the transistor 102 is originally started as a result of an increase of the conversion signal LVI to the inverter threshold, and therefore is a positive feedback operation for accelerating this action. The transistor 85 as a current source of the differential input circuit 61 is set such that extremely small current flows per one circuit because a huge number of circuits parallelly and simultaneously operate in the imaging device 1. Moreover, the reference signal REF is swept very slowly because the voltage changing in a unit time for switching of a time code has an LSB step of AD conversion. Accordingly, the gate potential of the transistor 86 also changes slowly, and the output current of the transistor 86 driven by such slow change also changes slowly. However, the output signal VCO can achieve sufficiently high-speed transition by applying positive feedback from a subsequent stage to the conversion signal LVI charged by the foregoing output current. It is preferable that the transition time of the output signal VCO be a fraction of the unit time of the time code, and 1 ns or shorter in a typical example. The comparison circuit 51 according to the present disclosure can achieve this output transition time only by setting a small current of 0.1 uA, for example, for the transistor 85 as the current source.

### Detailed Configuration Example of Pixel Circuit

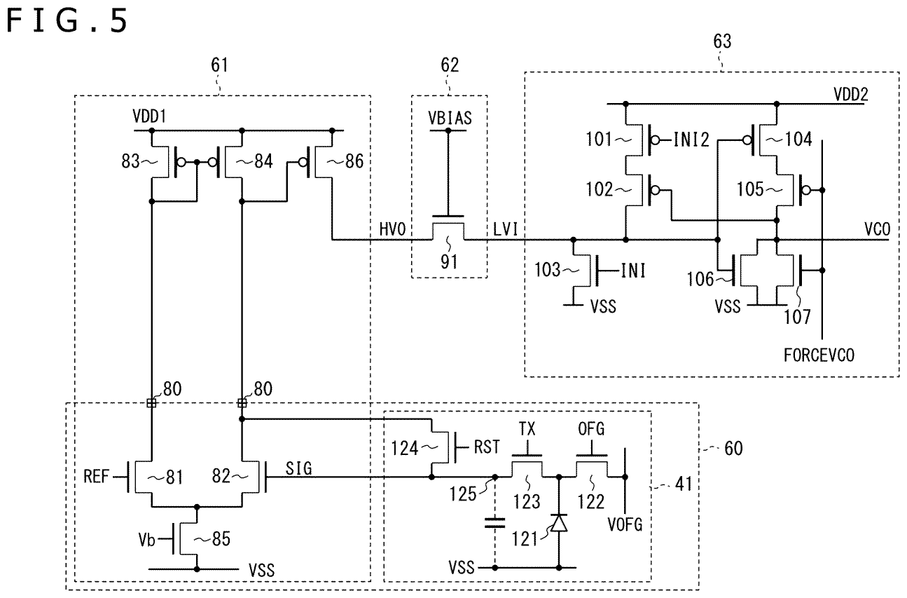

A detailed configuration of the pixel circuit 41 will be described with reference to FIG. 5.

FIG. 5 is a circuit diagram depicting details of the pixel circuit 41 in addition to the comparison circuit 51 depicted in FIG. 3.

The pixel circuit 41 includes a photodiode (PD) 121 as a photoelectric conversion element, a discharge transistor 122, a transfer transistor 123, a reset transistor 124, and an FD (floating diffusion layer) 125. A ground node VSS' for the pixel circuit 41 is provided separately from the ground nodes VSS for the differential input circuit 61 and the positive feedback circuit 63 included in the comparison circuit 51.

The discharge transistor 122 is used for adjustment of an exposure period. Specifically, if the discharge transistor 122 is turned on when the exposure period is desired to be started at certain timing, charge accumulated in the photodiode 121 by that time is discharged. Accordingly, the exposure period is started after the discharge transistor 122 is turned off.

The transfer transistor 123 transfers charge generated by the photodiode 121 to the FD 125. The reset transistor 124 resets charge retained in the FD 125. The FD 125 is connected to the gate of the transistor 82 of the differential input circuit 61. In this manner, the transistor 82 of the differential input circuit 61 is allowed to also function as an amplification transistor of the pixel circuit 41.

A source of the reset transistor 124 is connected to the gate of the transistor 82 of the differential input circuit 61 and to the FD 125, while a drain of the reset transistor 124 is connected to the drain of the transistor 82. Accordingly, a fixed reset voltage for resetting charge of the FD 125 is absent. This configuration is adopted to allow any setting of the reset voltage for resetting the FD 125 with use of the reference signal REF by controlling a circuit state of the differential input circuit 61.

### <Pixel Unit Timing Chart>

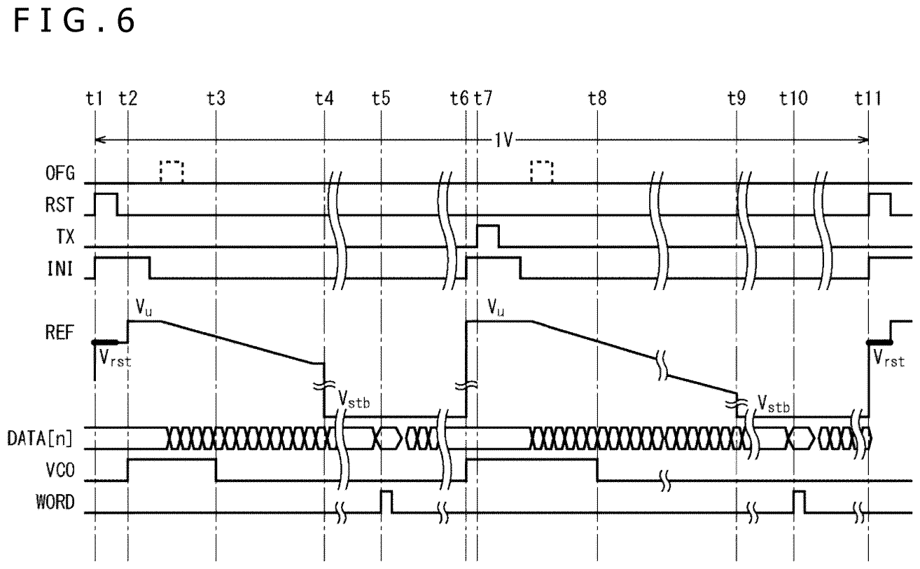

An operation of the pixel 21 having the pixel circuit 41 and the comparison circuit 51 in FIG. 5 will be described with reference to a timing chart in FIG. 6.

Initially, at a time t1, the reference signal REF is changed from a standby voltage V_{stb}, which has been previously set, to a reset voltage Vrst for resetting charge of the FD 125, and the reset transistor 124 is turned on. As a result, the charge of the FD 125 is reset. Moreover, at the time t1, the initializing signal INI and the not-illustrated initializing signal INI2 supplied to the gates of the transistors 103 and 101, respectively, of the positive feedback circuit 63 are set to high-level signals to set the positive feedback circuit 63 to an initial state.

At a time t2, the reference signal REF changes to a predetermined voltage Vu to start comparison between the reference signal REF and the pixel signal SIG (sweeping of reference signal REF). At this time, the reference signal REF is higher than the pixel signal SIG. Accordingly, the output signal VCO becomes a high-level signal.

At a time t3, it is determined that the reference signal REF and the not-illustrated pixel signal SIG are equalized, and the output signal VCO is inverted (changed to a low level). After inversion of the output signal VCO, the positive feedback circuit 63 increases inversion speed of the output signal VCO as described above. Moreover, the data storage unit 52 retains (stores) time data (N-bit time code DATA[1] to DATA[N]) at the time of inversion of the output signal VCO.

At a time t4 which is a time of completion of a signal write period and a start time of a signal read period, the voltage of the reference signal REF supplied to the gate of the transistor 81 of the comparison circuit 51 is lowered to a level for turning off the transistor 81 (standby voltage V_{stb}). In this manner, current consumed by the comparison circuit 51 during the signal read period is reduced.

At a time t5, the WORD signal for controlling read timing is brought into a high-level state, and the retained (stored) N-bit time code DATA[1] to DATA[N] are output from the latch control circuit 71 of the data storage unit 52. The time codes acquired at this step correspond to P-phase data at a reset level at the time of CDS (Correlated Double Sampling) processing.

At a time t6, the reference signal REF is raised to the predetermined voltage Vu, and the initializing signals INI and INI2 supplied to the gates of the transistors 103 and 101, respectively, are set to high-level signals to again set the positive feedback circuit 63 to the initial state.

At a time t7, the transfer transistor 123 of the pixel circuit 41 is turned on in response to a high-level transfer signal TX to transfer charge accumulated in the photodiode 121 to the FD 125.

The initializing signal INI and the not-illustrated initializing signal INI2 are returned to low-level signals. Thereafter, comparison between the reference signal REF and the pixel signal SIG (sweeping of the reference signal REF) is started. At this time, the reference signal REF is higher than the pixel signal SIG. Accordingly, the output signal VCO is a high-level signal.

Subsequently, at a time t8, it is determined that the reference signal REF and the not-illustrated pixel signal SIG are equalized, and the output signal VCO is inverted (changed to the low level). After inversion of the output signal VCO, the positive feedback circuit 63 increases inversion speed of the output signal VCO. Moreover, the data storage unit 52 retains (stores) the time data (N-bit time code DATA[1] to DATA[N]) at the time of inversion of the output signal VCO.

At a time t9 which is a time of completion of a signal write period and a start time of a signal read period, the voltage of the reference signal REF supplied to the gate of the transistor 81 of the comparison circuit 51 is lowered to the level for turning off the transistor 81 (standby voltage V_{stb}). In this manner, current consumed by the comparison circuit 51 during the signal read period is reduced.

At a time t10, the WORD signal for controlling read timing becomes a high-level signal, and the retained (stored) N-bit time code DATA[1] to DATA[N] are output from the latch control circuit 71 of the data storage unit 52. The time codes acquired at this step correspond to D-phase data at a signal level at the time of CDS processing. A state at a time t11 is identical to the state at the time t1 described above and corresponds to driving of subsequent 1V (1 vertical scanning period).

According to the driving of the pixel 21 described above, P-phase data at the reset level is initially acquired and then read, and subsequently D-phase data at a signal level is acquired and read.

The operation described above achieves a global shutter operation which simultaneously resets all of the pixels 21 included in the pixel array unit 22 of the imaging device 1 and simultaneously exposes all of the pixels 21. The simultaneous exposure and read of all the pixels thus achieved can eliminate the necessity of providing a retaining unit which is usually provided within a pixel to retain charge until reading of charge. Moreover, this configuration of the pixel 21 also eliminates the necessity of providing a selection transistor or the like required by the imaging device 1 of a column parallel read type to select a pixel to which the pixel signal SIG is output.

According to the driving of the pixel 21 described with reference to FIG. 6, the discharge transistor 122 is constantly controlled in an off-state. However, as indicated by broken lines in FIG. 6, any exposure period may be set by setting a discharge signal OFG to a high-level signal at each desired time to temporarily turn on the discharge transistor 122, and then turning off the discharge transistor 122.

### <Data Storage Unit and Time Code Transfer Unit>

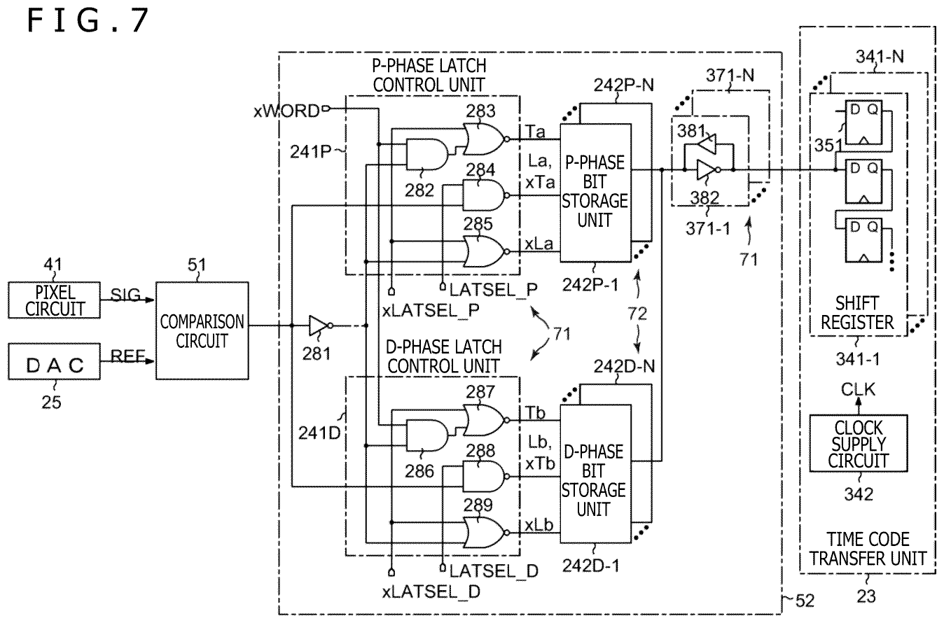

FIG. 7 is a circuit diagram depicting specific configurations of the time code transfer unit 23 and the data storage unit 52. The time code transfer unit 23 has N shift registers 341-1 to 341-N corresponding to the N-bit time code DATA[1] to DATA[N], and a clock supply circuit 342. Each of the N shift registers 341-1 to 341-N includes a plurality of D-F/Fs (D-flipflops) 351. The clock supply circuit 342 supplies a clock signal CLK to each of clock inputs of the D-F/Fs 351 of the shift registers 341. As described above, in a case where time codes are transferred for each cluster including a plurality of adjoining pixels 21, each of the shift registers 341 included in the time code transfer unit 23 has the same number of the D-F/Fs 351 as the number of the clusters.

The latch control circuit 71 included in the data storage unit 52 has a P-phase latch control unit 241P for P-phase data, a D-phase latch control unit 241D for D-phase data, and N bidirectional buffer circuits 371-1 to 371-N.

Meanwhile, the latch storage unit 72 included in the data storage unit 52 has P-phase bit storage units (first storage units) 242P-1 to 242P-N for P-phase data and D-phase bit storage units (second storage units) 242D-1 to 242D-N for D-phase data.

The N bidirectional buffer circuits 371-1 to 371-N are provided for the N shift registers 341-1 to 341-N of the time code transfer unit 23 with one-to-one correspondence. Each of the bidirectional buffer circuits 371 is connected to one of the D-F/Fs 351 included in the corresponding shift register 341.

The write control signal WR which becomes a high-level signal during the write operation of the time code is supplied to a buffer circuit 381 of the bidirectional buffer circuit 371-n (0<n<N+1), while the read control signal RD which becomes a high-level signal during the read operation of the time code is supplied to an inverter circuit 382. The bidirectional buffer circuit 371-n switches between the write operation and the read operation of the time code for each of the P-phase bit storage units 242P-1 to 242P-N and each of the D-phase bit storage units 242D-1 to 242D-N on the basis of the write control signal WR and the read control signal RD.

The P-phase latch control unit 241P and the D-phase latch control unit 241D have the same internal configuration. The P-phase latch control unit 241P has an AND gate 282, a NOR gate 283, a NAND gate 284, and a NOR gate 285. The D-phase latch control unit 241D has an AND gate 286, a NOR gate 287, a NAND gate 288, and a NOR gate 289.

The AND gate 282 outputs a logical AND signal obtained by logical AND of an xWORD signal and a signal obtained after inversion of the VCO signal by the inverter 281. The NOR gate 283 outputs a NOR signal Ta obtained by logical NOR of an output signal from the AND gate 282 and an xLATSEL_P signal which is an inverted signal of a P-phase/D-phase selection signal. The NAND gate 284 outputs negative AND signals La and xTa each obtained by negative AND of a LATSEL_P signal and the VCO signal. The NOR gate 285 outputs a NOR signal xLa obtained by logical NOR of the xLATSEL_P signal and the inverted signal of the VCO signal.

The AND gate 286 outputs a logical AND signal obtained by logical AND of the xWORD signal and the signal obtained after inversion of the VCO signal by the inverter 281. The NOR gate 287 outputs a NOR signal Tb obtained by logical NOR of an output signal from the AND gate 286 and an xLATSEL_D signal which is an inverted signal of a P-phase/D-phase selection signal. The NAND gate 288 outputs negative AND signals Lb and xTb each obtained by negative AND of a LATSEL_D signal and the VCO signal. The NOR gate 289 outputs a NOR signal xLb obtained by logical NOR of the xLATSEL_D signal and the inverted signal of the VCO signal.

The data storage unit 52 in FIG. 7 alternately performs a P-phase data AD conversion process and a D-phase data AD conversion process and alternately performs storage of P-phase data in the P-phase bit storage units 242P-1 to 242P-N and storage of D-phase data in the D-phase bit storage units 242D-1 to 242D-N.

Thereafter, the P-phase data and the D-phase data are sequentially output to the time code transfer unit 23.

In this manner, the data storage unit 52 in FIG. 7 can enhance offset and noise cancellation effects of the CDS process by reducing a time gap between P-phase data acquisition and D-phase data acquisition. Moreover, the sequential output of P-phase data and D-phase data to the time code transfer unit 23 eliminates the necessity of providing a memory unit for the output unit 28 to temporarily store P-phase data.

In the time code write operation, the WORD signal becomes a low-level signal for all of the pixels, and the latch storage unit 72 including the P-phase bit storage units 242P-1 to 242P-N and the N-phase bit storage units 242D-1 to 242D-N stores a time code input via the bidirectional buffer circuit 371-n, when the output signal VCO is a high-level signal. Moreover, the latch storage unit 72 retains a stored time code when the output signal VCO is a low-level signal.

In the time code read operation, the high-level WORD signal is supplied to only the P-phase latch control unit 241P and the D-phase latch control unit 241D of the pixel 21 corresponding to a read target. The output signal VCO is set to a low-level signal. Accordingly, a time code retained in the latch storage unit 72 is output to the time code transfer unit 23 via the bidirectional buffer circuit 371-n.

During the AD conversion period in which sweeping of the reference signal REF is carried out, each of the N shift registers 341 of the time code transfer unit 23 transfers a time code supplied from the time code generation unit 26, according to a shift clock which designates a unit time of the time code as a clock cycle.

In the time code write operation, the high-level write control signal WR and the low-level read control signal RD are supplied to each of the bidirectional buffer circuits 371. Each of the bidirectional buffer circuits 371 stores a time code supplied from the predetermined D-F/F 351 of the shift register 341 in the corresponding one of the P-phase bit storage unit 242P-1 to 242P-N or the D-phase bit storage units 242D-1 to 242D-N.

In the subsequent time code read operation, the low-level write control signal WR and the high-level read control signal RD are supplied to each of the bidirectional buffer circuits 371. The time code stored in the corresponding one of the P-phase bit storage units 242P-1 to 242P-N or the D-phase bit storage units 242D-1 to 242D-N is supplied to the predetermined D-F/F 351 of the shift register 341 of the time code transfer unit 23 via the bidirectional buffer circuit 371. Each of the shift registers 341 transfers time data, which has been supplied to the D-F/Fs 351 in the respective stages, to the output unit 28 forward and outputs the time data.

More specifically, each of the D-F/Fs 351 of the shift registers 341 is configured to come into a high-impedance state (hereinafter referred to as a Hi-Z state) when the clock signal CLK supplied to the clock input is either a high-level signal or a low-level signal. For example, according to the configuration of the D-F/Fs 351 in FIG. 7, each of the D-F/Fs 351 comes into the Hi-Z state when the clock signal CLK is a low-level signal.

The high-level read control signal RD is supplied to the corresponding bidirectional buffer circuit 371 in a period in which each of the D-F/Fs 351 of the shift registers 341 is brought into the Hi-Z state. In addition, the WORD signal becomes a high-level signal, and the time code stored in the corresponding one of the P-phase bit storage units 242P-1 to 242P-N or the D-phase bit storage units 242D-1 to 242D-N is supplied to the predetermined D-F/F 351 of the shift registers 341 of the time code transfer unit 23 via the corresponding bidirectional buffer circuit 371.

After the read control signal RD is returned to a low-level signal, a shift clock is supplied to each of the D-F/Fs 351 of the shift registers 341. Each of the shift registers 341 sequentially transfers time data, which has been supplied to the D-F/Fs 351 in the respective stages, to the output unit 28 and outputs the time data.

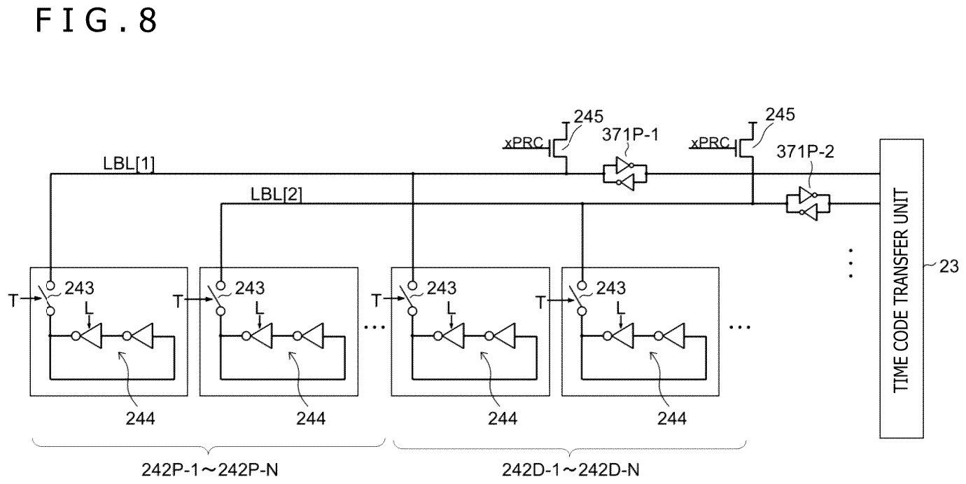

FIG. 8 is a circuit diagram depicting an example of an internal configuration of the P-phase bit storage units 242P-1 to 242P-N and the D-phase bit storage units 242D-1 to 242D-N included in the data storage unit 52. As depicted in FIG. 8, each of the P-phase bit storage units 242P-1 to 242P-N and the D-phase bit storage units 242D-1 to 242D-N (hereinafter also referred to as 242P and 242D) included in the data storage unit 52 has a switch 243 and a latch circuit 244, for example.

The latch circuit 244 is configured to connect a first inverter IV1 and a second inverter IV2 in a ring shape. The first inverter IV1 switches whether or not to execute an inversion output operation of an input signal, i.e., an output signal of the second inverter IV2, according to a first control signal L. For example, the first inverter IV1 executes the inversion output operation when the first control signal L is a high-level signal, but does not execute the inversion output operation and sets a high-impedance state of an output node when the first control signal L is a low-level signal. The second inverter IV2 has an input node connected to the output node of the first inverter IV1, and an output node connected to an input node of the first inverter IV1, and performs a normal inversion output operation. Specifically, the second inverter IV2 inverts and outputs the output signal of the first inverter IV1 and enters the inverted output signal into the first inverter IV1.

As depicted in FIG. 8, the P-phase bit storage units 242P-1 to 242P-N and the D-phase bit storage units 242D-1 to 242D-N are arranged side by side. One local bit line LBL is connected to a pair of one of the P-phase bit storage units 242P-1 to 242P-N and the corresponding D-phase bit storage unit 242D. For example, the P-phase bit storage unit 242P-1 and the D-phase bit storage unit 242D-1 are connected to the same local bit line LBL [1], and the P-phase bit storage unit 242P-2 and the D-phase bit storage unit 242D-2 are connected to the same local bit line LBL [2].

As described above, each of the local bit lines LBL [1:N] is connected to a corresponding pair of the P-phase bit storage unit 242P and the D-phase bit storage unit 242D. In the present description, the local bit lines LBL [1:N] will collectively be referred to as local bit lines (digital signal bit lines) LBL. Each of the local bit lines LBL achieves writing of a time code to the corresponding P-phase bit storage unit 242P and the corresponding D-phase bit storage unit 242D and reading of a time code from the corresponding P-phase bit storage unit 242P and the corresponding D-phase bit storage unit 242D by time division.

A pre-charge circuit 245 is connected to each of the local bit lines LBL [1:N]. The pre-charge circuit 245 includes an NMOS transistor, for example, and is pre-charged to a high level before writing of a time code to the data storage unit 52.

The switch 243 included in each of the P-phase bit storage units 242P-1 to 242P-N is controlled to be switched in response to outputs from the corresponding NOR gate 283 and the corresponding NAND gate 284 included in the P-phase latch control unit 241P. The switch 243 included in each of the D-phase bit storage units 242D-1 to 242D-N is controlled to be switched in response to outputs from the corresponding NOR gate 287 and the corresponding NAND gate 288 included in the D-phase latch control unit 241D. The latch circuit 244 included in each of the P-phase bit storage units 242P-1 to 242P-N switches whether or not to latch a time code output from the corresponding one of the bidirectional buffer circuits 371-1 to 371-N, in response to an output from the corresponding NAND gate 284 included in the P-phase latch control unit 241P. The latch circuit 244 included in each of the D-phase bit storage units 242D-1 to 242D-N switches whether or not to latch a time code output from the corresponding one of the bidirectional buffer circuits 371-1 to 371-N, in response to an output from the corresponding NAND gate 288 included in the D-phase latch control unit 241D.

As will be described below, each of the switches 243 in FIG. 7 includes a transfer gate where a PMOS transistor and an NMOS transistor are connected in parallel, for example. At the time of reading of data latched by each of the latch circuits 244 in FIG. 8, the NMOS transistor constituting the corresponding switch 243 is not turned on. This configuration is adopted for the following reason. When an impedance of each of the latch circuits 244 becomes lower than an impedance of the corresponding local bit line LBL at the time of reading of latch data, there is a possibility that data of the local bit line LBL is overwritten on the latch circuit 244. Accordingly, an L signal is used instead of an xT signal generated for input to a gate of the NMOS transistor constituting the switch 243.

Each of the xLATSEL_P signal and the xLATSEL_D signal in FIG. 7 is a signal for specifying the P-phase or the D-phase of the latch circuit 244 corresponding to a write target. This signal is generated not inside the data storage unit 52, but outside the data storage unit 52 and input to the data storage unit 52. In this manner, reduction of two inverters, i.e., four transistors, per one pixel is achievable. According to the case of the pixel ADC, the same number of ADCs as the number of the pixels are required. This configuration therefore enhances a circuit scale reduction effect.

The xWORD signal as an inversion signal of the WORD signal is supplied to the data storage unit 52 in FIG. 7. This is because the xWORD signal as an inverse logic of the WORD signal needs to be input so as to minimize the number of transistors included in the P-phase latch control unit 241P and the D-phase latch control unit 241D.

The latch circuit 244 may include a semiconductor memory such as a SRAM (Static Random Access Memory) including a plurality of transistors. In this case, each of the P-phase latch control units 241P and the D-phase latch control units 241D needs to have a control circuit configuration optimized for the configuration of the semiconductor memory to be adopted. It is preferable that each of the P-phase latch control units 241P and the D-phase latch control units 241D have an assembly of combinational circuits rather than sequential circuits in view of the necessity that each of the P-phase latch control units 241P and the D-phase latch control units D is contained in a limited area.

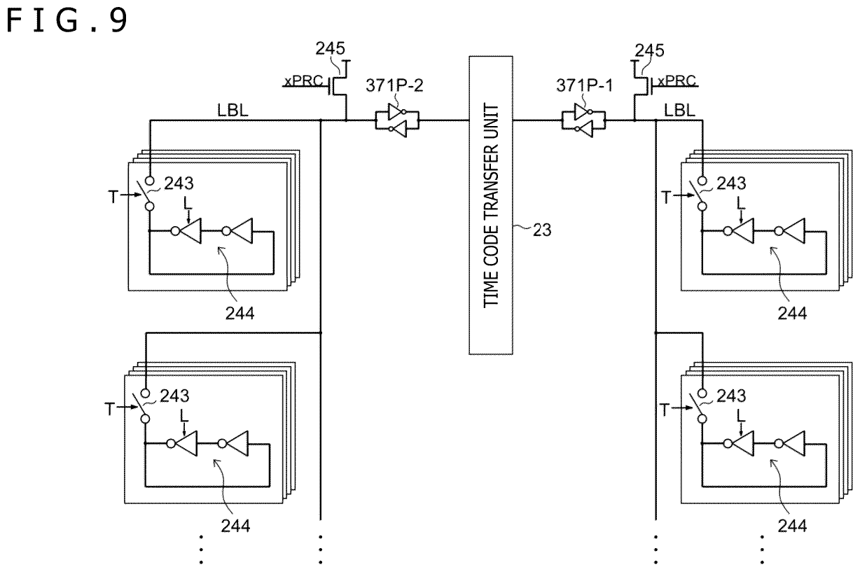

While FIG. 8 depicts the example where each of the local bit lines LBL is shared by the corresponding P-phase bit storage unit 242P and the corresponding D-phase bit storage unit 242D, each of the time code transfer units 23 performs transfer for the pixels 21 located on both sides of the time code transfer unit 23 as depicted in FIG. 1. Moreover, each of the time code transfer units 23 transfers time codes for each cluster including a plurality of adjoining pixels 21. In this case, each of the local bit lines LBL may be shared by a plurality of the latch storage units 72 included in the plurality of pixels 21 of each cluster as depicted in FIG. 9.

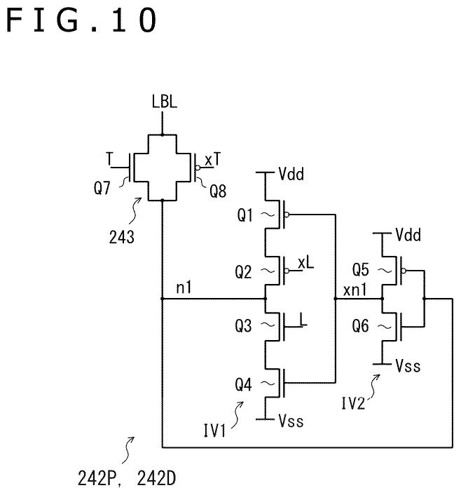

FIG. 10 is a specific circuit diagram of each of the P-phase bit storage units 242P-1 to 242P-N and the D-phase bit storage units 242D-1 to 242D-N (242P, 242D) and includes the first inverter IV1 and the second inverter IV2 connected in a ring shape and the switch 243 as described above.

The first inverter IV1 has a first transistor Q1, a second transistor Q2, a third transistor Q3, and a fourth transistor Q4 connected by cascode connection between a power source voltage node (first reference voltage node) Vdd and a ground node (second reference voltage node) Vss. Each of the first transistor Q1 and the second transistor Q2 is a PMOS transistor, while each of the third transistor Q3 and the fourth transistor Q4 is an NMOS transistor.

The first transistor Q1 has a source connected to the power source voltage node Vdd, and a gate connected to an output node xn1 of the second inverter IV2. The second transistor Q2 has a source connected to a drain of the first transistor Q1, a gate to which an inversion signal xL of the first control signal L is input, and a drain connected to an output node n1 of the first inverter IV1. The third transistor Q3 has a drain connected to the drain of the second transistor Q2 and the output node n1 of the first inverter IV1, and a gate to which the first control signal L is input. The fourth transistor Q4 has a drain connected to a source of the third transistor Q3, a source connected to the ground node Vss, and a gate connected to the output node xn1 of the second inverter IV2.

The second inverter IV2 has a fifth transistor Q5 and a sixth transistor Q6 connected by cascode connection between the power source voltage node Vdd and the ground node Vss. The fifth transistor Q5 is a PMOS transistor, while the sixth transistor Q6 is an NMOS transistor.

The fifth transistor Q5 has a source connected to the power source voltage node Vdd, a drain connected to the gate of the first transistor Q1 and the gate of the fourth transistor Q4, and a gate connected to the output node n1 of the first inverter IV1. The sixth transistor Q6 has a drain connected to the drain of the fifth transistor Q5, a source connected to the ground node Vss, and a gate connected to the output node n1 of the first inverter IV1.

The switch 243 in FIG. 10 can include a transfer gate having a seventh transistor Q7 and an eighth transistor Q8. The seventh transistor Q7 is an NMOS transistor, while the eighth transistor Q8 is a PMOS transistor. A drain of the seventh transistor Q7 and a source of the eighth transistor Q8 are connected to the local bit line LBL, while a source of the seventh transistor Q7 and a drain of the eighth transistor Q8 are connected to the output node n1 of the first inverter IV1. A second control signal T is input to a gate of the seventh transistor Q7, while an inversion signal xT of the second control signal T is input to a gate of the eighth transistor Q8.

For example, when the second control signal T becomes a high-level signal in a low-level state of the local bit line LBL, the output node n1 of the first inverter IV1 and the output node xn1 of the second inverter IV2 come into a low level and a high level, respectively. Accordingly, the first transistor Q1 is turned off, and the fourth transistor Q4 is turned on. When the first control signal L becomes a high-level signal in this condition, the output node n1 of the first inverter IV1 comes into a low level. Accordingly, the latch circuit 244 in FIG. 10 maintains a low level.

On the other hand, when the second control signal T becomes a high-level signal in a high-level state of the local bit line LBL, the output node n1 of the first inverter IV1 and the output node xn1 of the second inverter IV2 come into a high level and a low level, respectively. Accordingly, the first transistor Q1 is turned off, and the fourth transistor Q4 is turned on. When the first control signal L becomes a high-level signal in this condition, the output node n1 of the first inverter IV1 comes into a high level. Accordingly, the latch circuit 244 in FIG. 10 maintains a high level.

As depicted in FIG. 10, each of the P-phase bit storage units 242P-1 to 242P-N and the D-phase bit storage units 242D-1 to 242D-N (242P, 242D) may include eight transistors, for example. The circuit in FIG. 10 may be formed on a semiconductor substrate. The present inventor has invented a layout for arranging the circuit in FIG. 10 in a small circuit area.

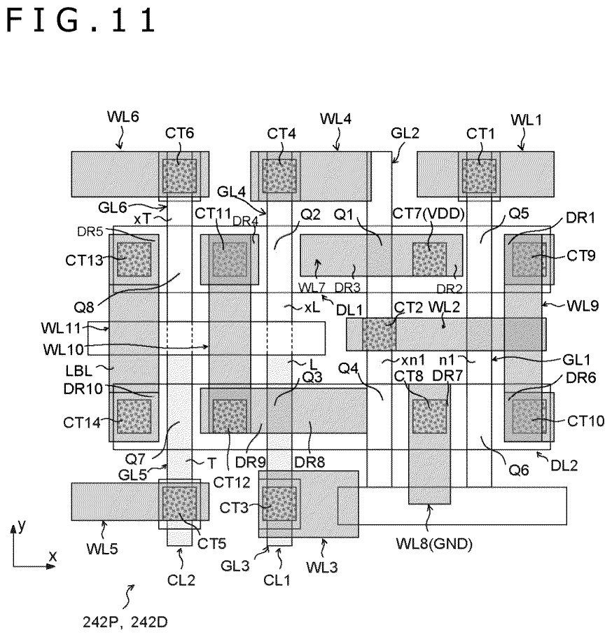

FIG. 11 is a diagram depicting an example of the layout for arranging the circuit in FIG. 10. Note that the layout for arranging the circuit in FIG. 10 has various modifications in addition to the arrangement depicted in FIG. 11 and therefore is not limited to the arrangement in FIG. 11.

As depicted in FIG. 11, the circuit in FIG. 10 has a first diffusion layer DL1 and a second diffusion layer DL2, first to sixth gate layers GL1 to GL6, first to eleventh wiring layers WL1 to WL11, and first to tenth diffusion regions DR1 to DR10.

The first diffusion layer DL1 and the second diffusion layer DL2 extend in a first direction X and are disposed away from each other in a second direction Y crossing the first direction X. For example, the first diffusion layer DL1 and the second diffusion layer DL2 are disposed in a well region. For example, each of the first diffusion layer DL1 and the second diffusion layer DL2 is a P+ diffusion layer.

The first to sixth gate layers GL1 to GL6 are disposed on the first diffusion layer DL1 and the second diffusion layer DL2. The first to sixth gate layers GL1 to GL6 each extend in the second direction Y and are disposed away from each other in the first direction X.

The first wiring layer WL1 is disposed on the first gate layer GL1 via a first contact CT1. Accordingly, the first wiring layer WL1 is conductively connected to the first gate layer GL1.

The second wiring layer WL2 is disposed on the second gate layer GL2 via a second contact CT2. Accordingly, the second wiring layer WL2 is conductively connected to the second gate layer GL2.

The third wiring layer WL3 is disposed on the third gate layer GL3 via a third contact CT3. Accordingly, the third wiring layer WL3 is conductively connected to the third gate layer GL3.

The fourth wiring layer WL4 is disposed on the fourth gate layer GL4 via a fourth contact CT4. Accordingly, the fourth wiring layer WL4 is conductively connected to the fourth gate layer GL4.

The fifth wiring layer WL5 is disposed on the fifth gate layer GL5 via a fifth contact CT5. Accordingly, the fifth wiring layer WL5 is conductively connected to the fifth gate layer GL5.

The sixth wiring layer WL6 is disposed on the sixth gate layer GL6 via a fifth contact CT6. Accordingly, the sixth wiring layer WL6 is conductively connected to the sixth gate layer GL6.

The first to fifth diffusion regions DR1 to DR5 are disposed away from each other inside the first diffusion layer DL1. The sixth to tenth diffusion regions DR6 to DR10 are disposed away from each other inside the second diffusion layer DL2.

The seventh wiring layer WL7 is disposed on the second diffusion region DR2 via a seventh contact CT7 and conductively connected to the power source voltage node Vdd (first reference voltage node). The eighth wiring layer WL8 is disposed on the seventh diffusion region DR7 via an eighth contact CT8 and conductively connected to the ground node Vss (second reference voltage node).

The ninth wiring layer WL9 is disposed on the first diffusion region DR1 via a ninth contact CT9 and disposed on the sixth diffusion region DR6 via a tenth contact CT10. The tenth wiring layer WL10 is disposed on the fourth diffusion region DR4 via an eleventh contact CT11 and disposed on the ninth diffusion region DR9 via a twelfth contact CT12. The eleventh wiring layer WL11 is disposed on the fifth diffusion region DR5 via a thirteenth contact CT13 and disposed on the tenth diffusion region DR10 via a fourteenth contact CT14.

The first gate layer GL1 is connected to the gate of the fifth transistor Q5 and the gate of the sixth transistor Q6. The second gate layer GL2 is connected to the gate of the first transistor Q1 and the gate of the fourth transistor Q4. The third gate layer GL3 is connected to the gate of the third transistor Q3. The fourth gate layer GL4 is connected to the gate of the second transistor Q2. The fifth gate layer GL5 is connected to the gate of the seventh transistor Q7. The sixth gate layer GL6 is connected to the gate of the eighth transistor Q8.

The first diffusion region DR1 is a source region of the fifth transistor Q5. The second diffusion region DR2 is a drain region of the fifth transistor Q5 and a source region of the first transistor Q1. The third diffusion region DR3 is a drain region of the first transistor Q1 and a source region of the second transistor Q2. The fourth diffusion region DR4 is a drain region of the second transistor Q2 and a drain region of the eighth transistor Q8. The fifth diffusion region DR5 is a source region of the eighth transistor Q8. The sixth diffusion region DR6 is a drain region of the sixth transistor Q6. The seventh diffusion region DR7 is a source region of the sixth transistor Q6 and a source region of the fourth transistor Q4. The eighth diffusion region DR8 is a drain region of the fourth transistor Q4 and a source region of the third transistor Q3. The ninth diffusion region DR9 is a drain region of the third transistor Q3 and a source region of the seventh transistor Q7. The tenth diffusion region DR10 is a drain region of the seventh transistor Q7.

Each of the first transistor Q1, the second transistor Q2, the fifth transistor Q5, and the eighth transistor Q8 disposed on the first diffusion layer DL1 is a PMOS transistor. Each of the third transistor Q3, the fourth transistor Q4, the sixth transistor Q6, and the seventh transistor Q7 disposed on the second diffusion layer DL2 is an NMOS transistor. Accordingly, the first diffusion layer DL1 is provided as a layer where the group of PMOS transistors is arranged, while the second diffusion layer DL2 is provided as a layer where the group of NMOS transistors is arranged.

The third gate layer GL3 in FIG. 11 is a partial conductive layer which is one of two divisions of the first conductive layer CL1 that extends in the second direction Y and that is separated by a cut mask. The fourth gate layer GL4 is the other partial conductive layer of the two divisions of the first conductive layer CL1.

Similarly, the fifth gate layer GL5 is a partial conductive layer which is one of two divisions of the second conductive layer CL2 that extends in the second direction Y and that is separated by a cut mask. The sixth gate layer GL6 is the other partial conductive layer of the two divisions of the second conductive layer CL2.

In this manner, the third gate layer GL3 and the fourth gate layer GL4 are formed by cutting the first conductive layer CL1 with use of the cut mask, and the fifth gate layer GL5 and the sixth gate layer GL6 are formed by cutting the second conductive layer CL2 with use of the cut mask. Accordingly, a manufacturing step can be simplified, and positional deviation between the third to sixth gate layers GL3 to GL6 can be reduced.

While the one first diffusion layer DL1 and the one second diffusion layer DL2 are disposed in the second direction Y in FIG. 11, the number of the first diffusion layers DL1 and the number of the second diffusion layers DL2, which are disposed in the second direction Y, are not limited to any specific numbers.

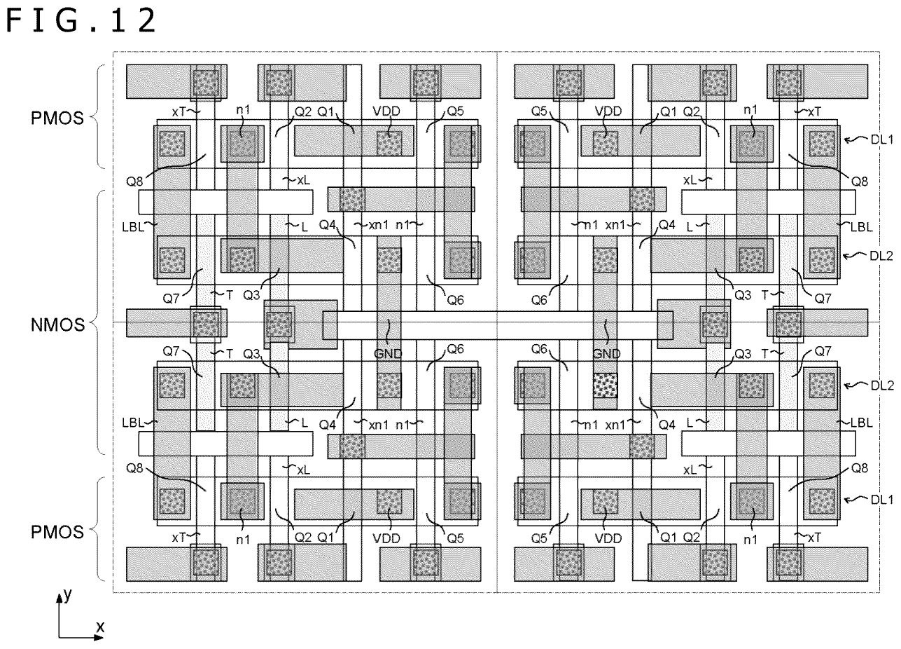

FIG. 12 is a diagram depicting a layout for arranging a plurality of bits. While FIG. 12 depicts an example where two bits are arranged in each of the first direction X and the second direction Y, the number of bits arranged in each of the first direction X and the second direction Y is not limited to any specific number.

The two first diffusion layers DL1 and the two second diffusion layers DL2 are arranged in the second direction Y in FIG. 12. These diffusion layers are arranged along the second direction Y in an order of the first diffusion layer DL1, the second diffusion layer DL2, the second diffusion layer DL2, and the first diffusion layer DL1. As described above, the group of PMOS transistors is arranged in the first diffusion layer DL1, while the group of NMOS transistors is arranged in the second diffusion layer DL2.

In FIG. 12, the first to sixth gate layers GL1 to GL6, the first to eleventh wiring layers WL1 to WL11, and the first to tenth diffusion regions DR1 to DR10 of two bits disposed adjacently to each other in the first direction X are line-symmetrically arranged with respect to a boundary line (first boundary line) extending in the second direction Y.

In addition, in FIG. 12, the first to sixth gate layers GL1 to GL6, the first to eleventh wiring layers WL1 to WL11, and the first to tenth diffusion regions DR1 to DR10 of two bits disposed adjacently to each other in the second direction Y are line-symmetrically arranged with respect to a boundary line (second boundary line) extending in the first direction X.

As described above, the first to sixth gate layers GL1 to GL6, the first to eleventh wiring layers WL1 to WL11, and the first to tenth diffusion regions DR1 to DR10 of two bits disposed adjacently to each other in each of the first direction X and the second direction Y in FIG. 12 are line-symmetrically arranged with respect to each of the first boundary line extending in the first direction X and the second boundary line extending in the second direction Y.

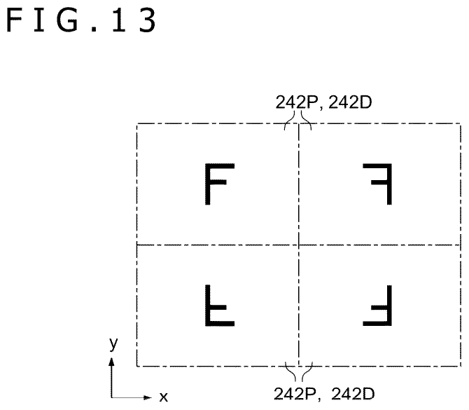

FIG. 13 is a diagram schematically depicting arrangement directions of the four bits in FIG. 12. In FIG. 13, the arrangement direction of each bit of the 2×2 bits depicted in FIG. 12 is expressed by a character “F.” The respective bits can be efficiently arranged in a small area by line-symmetrical positioning of the respective bits with respect to the boundary lines in the first direction X and the second direction Y.

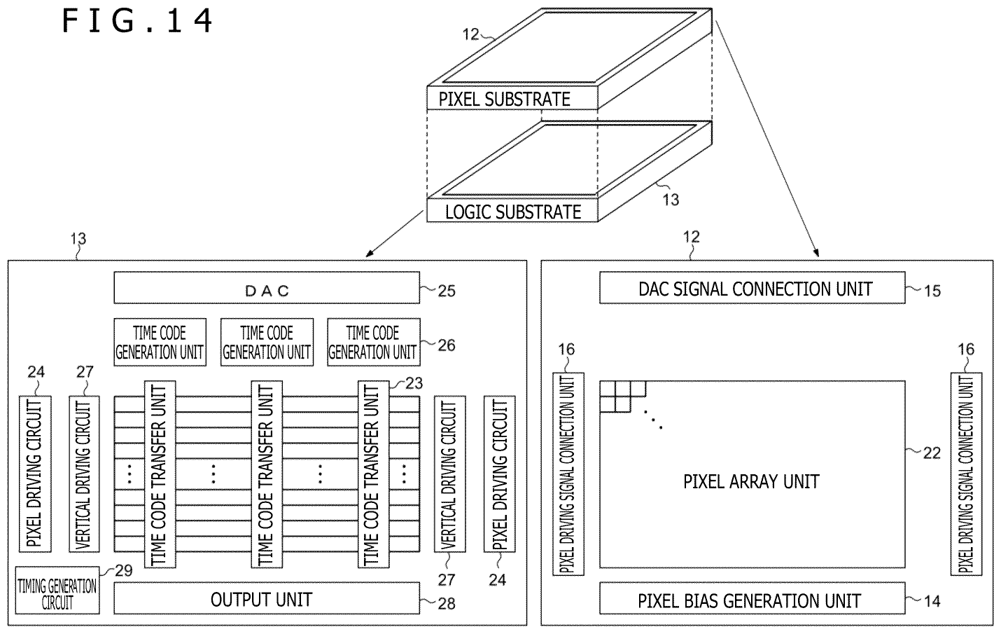

The imaging device 1 according to the present embodiment can be formed by laminating two substrates. FIG. 14 is a diagram depicting an example of the imaging device 1 formed by laminating a pixel substrate (first substrate) 12 and a logic substrate (second substrate) 13. The pixel substrate 12 is disposed on a light entrance surface side, and the logic substrate 13 is disposed below the pixel substrate 12. The pixel substrate 12 and the logic substrate 13 are joined to each other by Cu—Cu junction, bias, bumps, or other methods.

The pixel array unit 22, a pixel bias generation unit 14, a DAC signal connection unit 15, and pixel driving signal connection units 16 are disposed on the pixel substrate 12. The pixel bias generation unit 14 generates a bias voltage supplied to each of the pixels included in the pixel array unit 22. The DAC signal connection unit 15 transmits and receives various types of signals to and from the DAC 25 included in the logic substrate 13. The pixel driving signal connection units 16 are disposed near both ends of the pixel array unit 22 in the horizontal direction to transmit and receive various types of signals for AD conversion to and from the logic substrate 13.

The pixel driving circuits 24, the DAC (D/A converter) 25, the time code generation units 26, the vertical driving circuits 27, the output unit 28, and the timing generation circuit 29 are formed on the logic substrate 13. While FIG. 14 depicts an example of the logic substrate 13 which has the vertical driving circuits 27 disposed on both sides in the horizontal direction, the vertical driving circuit 27 may be provided only on one side as depicted in FIG. 1.

The pixel bias generation unit 14 included in the pixel substrate 12 and the output unit 28 included in the logic substrate 13 transmit and receive various types of signals to and from each other via Cu—Cu junction or the like. Moreover, the DAC signal connection unit 15 included in the pixel substrate 12 and the DAC 25 included in the logic substrate 13 transmit and receive various types of signals to and from each other via Cu—Cu junction or the like. A reference signal generated by the DAC 25 is supplied to each of the pixels included in the pixel substrate 12. Accordingly, wires for reference signals formed on the pixel substrate 12 are arranged in a mesh shape. For reducing lengths of the wires, a plurality of vias are formed in the DAC signal connection unit 15 to supply reference signals to the pixel substrate 12 via the plurality of vias. Further, the pixel driving signal connection units 16 included in the pixel substrate 12 and the pixel driving circuits 24 included in the logic substrate 13 transmit and receive various types of signals to and from each other via Cu—Cu junction or the like.

The DAC signal connection unit 15 included in the pixel substrate 12 and the DAC 25 included in the logic substrate 13 are disposed at positions overlapping each other in a lamination direction. However, the DAC signal connection unit 15 and the DAC 25 are not necessarily required to have the same area. Similarly, a part of the pixel bias generation unit 14 included in the pixel substrate 12 and a part of the output unit 28 included in the logic substrate 13 may be or may not be disposed at positions overlapping each other in the lamination direction. The pixel bias generation unit 14 and the output unit 28 are not necessarily required to have the same area. In addition, the pixel driving signal connection units 16 included in the pixel substrate 12 and the pixel driving circuits 24 included in the logic substrate 13 are only required to overlap each other at least partially. Each of the pixel driving signal connection units 16 and each of the pixel driving circuits 24 are not required to have the same area.

For example, the pixel circuit 41 included in a frame 60 in FIG. 5 and a part of the differential input circuit 61 included in the comparison circuit 51 are disposed on the pixel substrate 12, and the other components are disposed on the logic substrate 13.

While described above has been the example where each of the pixels 21 has the data storage unit 52 which includes the P-phase bit storage units 242P and the D-phase bit storage units 242D depicted in FIG. 10, it is also possible that the circuit configuration in FIG. 10 is formed as one memory cell to provide a semiconductor memory including a plurality of the memory cells.

As described above, according to the present embodiment, the latch storage unit 72 included in each of the pixels 21 has the eight transistors Q1 to 08 as depicted in FIG. 10. In this case, the first to fourth transistors Q1 to Q4 constitute the first inverter IV1, the fifth and sixth transistors Q5 and Q6 constitute the second inverter IV2, and the seventh and eighth transistors Q7 and Q8 constitute the switch (transfer gate) 243. The switch 243 is connected between the local bit line LBL and the output node n1 of the first inverter IV1. Accordingly, the latch storage unit 72 need not have a SRAM configuration to which a pair of data lines are connected.

Moreover, according to the present embodiment, the latch storage unit 72 in FIG. 9 has the layout depicted in FIGS. 11 and 12. Accordingly, high-density assembly is achievable.

### Examples of Application to Mobile Body

The technology according to the present disclosure (present technology) is applicable to various products. For example, the technology according to the present disclosure may be implemented as a device mounted on any type of mobile bodies, such as cars, electric cars, hybrid electric cars, motorcycles, bicycles, personal mobilities, airplanes, drones, vessels, and robots.

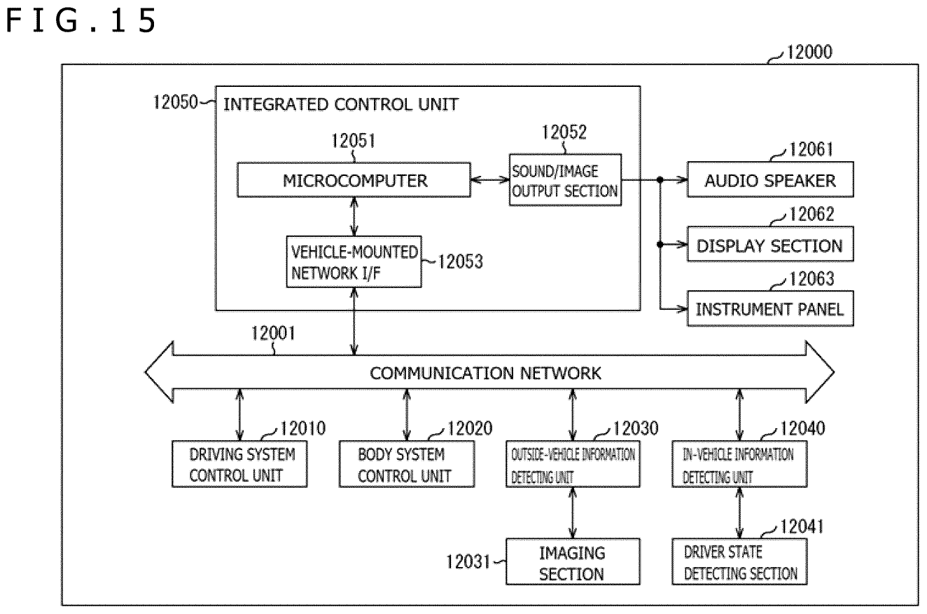

FIG. 15 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 15, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 15, an audio speaker 12061, a display section 12062, and an instrument panel 12063 are illustrated as the output device. The display section 12062 may, for example, include at least one of an on-board display and a head-up display.

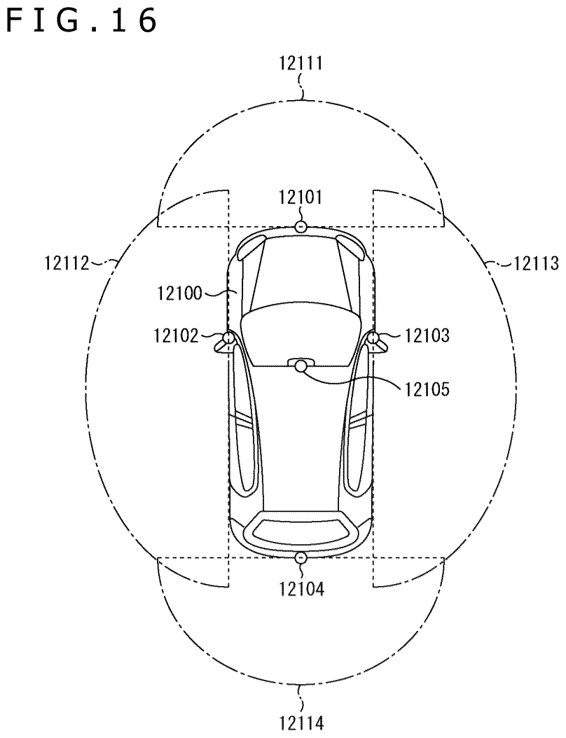

FIG. 16 is a diagram depicting an example of the installation position of the imaging section 12031.

In FIG. 16, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 16 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure is applicable has been described above. The technology according to the present disclosure is applicable to the imaging section 12031 and the like in the configuration described above. Specifically, the solid-state imaging device 1 according to the present disclosure is applicable to the imaging section 12031. Clearer captured images are acquirable by applying the technology according to the present disclosure to the imaging section 12031. Accordingly, fatigue reduction of the driver is achievable.

Note that the present technology can also adopt the following configurations.

(1)

An imaging device including:
a pixel array unit that has a plurality of pixels;
a time code generation unit that generates a time code changing with time;
a reference signal generation unit that generates a reference signal that has a voltage level changing with time; and
an AD converter that achieves analog-digital conversion of a pixel signal by comparison between the pixel signal and the reference signal, in which
the AD converter has a storage unit that stores the time code including a plurality of bits and corresponding to the pixel signal by comparison between the pixel signal and the reference signal,
the storage unit has, for each of the plurality of bits,
   a first inverter that switches whether or not to perform an inversion output operation of an input signal according to a first control signal, and
   a second inverter that has an input node connected to an output node of the first inverter and an output node connected to an input node of the first inverter, and
the first inverter has
   a first transistor that is of P-type and has a source connected to a first reference voltage node and a gate connected to the output node of the second inverter,
   a second transistor that is of P-type and has a source connected to a drain of the first transistor, a gate to which an inversion signal of the first control signal is input, and a drain connected to the output node of the first inverter,
   a third transistor that is of N-type and has a drain connected to the drain of the second transistor and the output node of the first inverter and a gate to which the first control signal is input, and
   a fourth transistor that is of N-type and has a drain connected to a source of the third transistor, a source connected to a second reference voltage node, and a gate connected to the output node of the second inverter.
      (2)

The imaging device according to (1), in which
the second inverter has
   a fifth transistor that is of P-type and has a source connected to the first reference voltage node, a drain connected to the gate of the first transistor and the gate of the fourth transistor, and a gate connected to the output node of the first inverter, and
   a sixth transistor that is of N-type and has a drain connected to the drain of the fifth transistor, a source connected to the second reference voltage node, and a gate connected to the output node of the first inverter.
      (3)

The imaging device according to (2), in which
bit data corresponding to a time code associated with the pixel signal is written to the storage unit via one digital signal bit line for each bit, and the bit data that corresponds to the time code and that is read from the storage unit is output to the one digital signal bit line.
   (4)

The imaging device according to (3), in which
the storage unit has, for each of the plurality of bits, a transfer gate connected between the output node of the first inverter and the digital signal bit line,
the transfer gate has a seventh transistor of N-type and an eighth transistor of P-type, the seventh transistor and the eighth transistor being connected in parallel between the output node of the first inverter and the digital signal bit line, and
a second control signal for controlling opening and closing of the transfer gate is input to each of gates of the seventh transistor and the eighth transistor.
   (5)

The imaging device according to (4), in which
the time code associated with the pixel signal is stored in the storage unit for each bit via the digital signal bit line and the transfer gate, and
the time code stored in the storage unit is read via the digital signal bit line and the transfer gate.
   (6)

The imaging device according to (4) or (5), in which
the storage unit has
   a first storage unit that stores the time code associated with the pixel signal at a reset level, and
   a second storage unit that stores the time codes associated with the pixel signals corresponding to intensity levels of each light entering the plurality of pixels, and
the first storage unit and the second storage unit share the digital signal bit line for each of the plurality of bits.
   (7)

The imaging device according to (6), in which
each of the first storage unit and the second storage unit has the first inverter, the second inverter, and the transfer gate, and
the same digital signal bit line is connected to the respective transfer gates of the first storage unit and the second storage unit included in the same bit.
   (8)

The imaging device according to (4) or (5), in which
a plurality of the storage units corresponding to a plurality of adjoining pixels read and write the bit data corresponding to the time code via the same digital signal bit line for each bit.
   (9)

The imaging device according to any one of (4) to (8), further including:
a first diffusion layer and a second diffusion layer each extending in a first direction and disposed away from each other in a second direction crossing the first direction;
a first gate layer, a second gate layer, a third gate layer, a fourth gate layer, a fifth gate layer, and a sixth gate layer disposed on the first diffusion layer and the second diffusion layer, each extending in the second direction, and disposed away from each other in the first direction;
a first wiring layer disposed on the first gate layer via a first contact;
a second wiring layer disposed on the second gate layer via a second contact;
a third wiring layer disposed on the third gate layer via a third contact;
a fourth wiring layer disposed on the fourth gate layer via a fourth contact;
a fifth wiring layer disposed on the fifth gate layer via a fifth contact;
a sixth wiring layer disposed on the sixth gate layer via a sixth contact;
a first diffusion region, a second diffusion region, a third diffusion region, a fourth diffusion region, and a fifth diffusion region disposed away from each other inside the first diffusion layer;
a sixth diffusion region, a seventh diffusion region, an eighth diffusion region, a ninth diffusion region, and a tenth diffusion region disposed away from each other inside the second diffusion layer;
a seventh wiring layer disposed on the second diffusion region via a seventh contact and conductively connected to the first reference voltage node;
an eighth wiring layer disposed on the seventh diffusion region via an eighth contact and conductively connected to the second reference voltage node;
a ninth wiring layer disposed on the first diffusion region via a ninth contact and disposed on the sixth diffusion region via a tenth contact;
a tenth wiring layer disposed on the fourth diffusion region via an eleventh contact and disposed on the ninth diffusion region via a twelfth contact; and
an eleventh wiring layer disposed on the fifth diffusion region via a thirteenth contact and disposed on the tenth diffusion region via a fourteenth contact,
   in which
the first gate layer is connected to the gate of the fifth transistor and the gate of the sixth transistor,
the second gate layer is connected to the gate of the first transistor and the gate of the fourth transistor,
the third gate layer is connected to the gate of the third transistor,
the fourth gate layer is connected to the gate of the second transistor,
the fifth gate layer is connected to the gate of the seventh transistor,
the sixth gate layer is connected to the gate of the eighth transistor,
the first diffusion region includes a source region of the fifth transistor,
the second diffusion region includes a drain region of the fifth transistor and a source region of the first transistor,
the third diffusion region includes a drain region of the first transistor and a source region of the second transistor,
the fourth diffusion region includes a drain region of the second transistor and a drain region of the eighth transistor,
the fifth diffusion region includes a source region of the eighth transistor,
the sixth diffusion region includes a drain region of the sixth transistor,
the seventh diffusion region includes a source region of the sixth transistor and a source region of the fourth transistor,
the eighth diffusion region includes a drain region of the fourth transistor and a source region of the third transistor,
the ninth diffusion region includes a drain region of the third transistor and a source region of the seventh transistor, and
the tenth diffusion region includes a drain region of the seventh transistor.
   (10)

The imaging device according to (9), in which
each of the first transistor, the second transistor, the fifth transistor, and the eighth transistor disposed on the first diffusion layer is of a first conductivity type, and
each of the third transistor, the fourth transistor, the sixth transistor, and the seventh transistor disposed on the second diffusion layer is of a second conductivity type.
   (11)

The imaging device according to (9) or (10), in which
four diffusion layers that include the first diffusion layer and the second diffusion layer are so disposed as to extend in the first direction,
the four diffusion layers are disposed away from each other in the second direction, and
transistor groups are disposed on the four diffusion layers in an order of a first conductivity type, a second conductivity type, the second conductivity type, and the first conductivity type in the second direction.
   (12)

The imaging device according to any one of (9) to (11), in which
the third gate layer is a partial conductive layer that is one of two divisions of a first conductive layer extending in the second direction, and
the fourth gate layer is the other partial conductive layer of the two divisions.
   (13)

The imaging device according to any one of (9) to (12), in which
the fifth gate layer is a partial conductive layer that is one of two divisions of a second conductive layer CL2 extending in the second direction, and
the sixth gate layer is the other partial conductive layer of the two divisions.
   (14)

The imaging device according to any one of (9) to (13), in which
the first to sixth gate layers, the first to eleventh wiring layers, and the first to tenth diffusion regions of two bits disposed adjacently to each other in the first direction within the storage unit are line-symmetrically disposed with respect to a boundary line extending in the second direction.
   (15)

The imaging device according to any one of (9) to (13), in which
the first to sixth gate layers, the first to eleventh wiring layers, and the first to tenth diffusion regions of two bits disposed adjacently to each other in the second direction within the storage unit are line-symmetrically disposed with respect to a boundary line extending in the first direction.
   (16)

The imaging device according to any one of (9) to (13), in which
the first to sixth gate layers, the first to eleventh wiring layers, and the first to tenth diffusion regions of two bits disposed adjacently to each other in each of the first direction and the second direction within the storage unit are line-symmetrically disposed with respect to each of a first boundary line extending in the first direction and a second boundary line extending in the second direction.
   (17)

The imaging device according to any one of (4) to (16), further including:
a pre-charge circuit that pre-charges the digital signal bit line to a predetermined potential before writing of the time code to the storage unit.
   (18)

The imaging device according to any one of (4) to (17), in which
the digital signal bit line performs writing of the time code to the storage unit and reading of the time code from the storage unit by time division.
   (19)

A semiconductor memory including:
a storage unit that includes a plurality of bits, in which
the storage unit has, for each of the plurality of bits,
   a first inverter that switches whether or not to perform an inversion output operation of an input signal according to a first control signal,
   a second inverter connected to an input node and an output node of the first inverter, and
   a transfer gate connected between the output node of the first inverter and a digital signal bit line,
the first inverter has
   a first transistor that is of P-type and has a source connected to a first reference voltage node and a gate connected to an output node of the second inverter,
   a second transistor that is of P-type and has a source connected to a drain of the first transistor, a gate to which an inversion signal of the first control signal is input, and a drain connected to an output node,
   a third transistor that is of N-type and has a drain connected to the drain of the second transistor and the output node and a gate to which the first control signal is input, and
   a fourth transistor that is of N-type and has a drain connected to a source of the third transistor, a source connected to a second reference voltage node, and a gate connected to the output node of the second inverter,
the second inverter has
   a fifth transistor that has a source connected to the first reference voltage node, a drain connected to the gate of the first transistor and the gate of the fourth transistor, and a gate connected to the drain of the second transistor and the drain of the third transistor, and
   a sixth transistor that has a drain connected to the gate of the first transistor and the gate of the fourth transistor, a source connected to the second reference voltage node, and a gate connected to the drain of the second transistor and the drain of the third transistor,
the transfer gate has a seventh transistor of N-type and an eighth transistor of P-type connected in parallel between the output node of the first inverter and the digital signal bit line, and
a second control signal for controlling opening and closing of the transfer gate is input to each of gates of the seventh transistor and the eighth transistor.

Modes of the present disclosure are not limited to the individual embodiment described above and include various modifications which can be conceived of by those skilled in the art. In addition, advantageous effects of the present disclosure are not limited to the specific effects described above. Accordingly, various additions, modifications, and partial deletions can be made without departing from the scope of the conceptual idea and the spirit of the present disclosure derived from contents specified in the claims and equivalents of the contents.

### REFERENCE SIGNS LIST

1: Imaging device
11: Semiconductor substrate
12: Pixel substrate
13: Logic substrate
14: Pixel bias generation unit
15: DAC signal connection unit
16: Pixel driving signal connection unit
21: Pixel
22: Pixel array unit
23: Time code transfer unit
24: Pixel driving circuit
26: Time code generation unit
27: Vertical driving circuit
28: Output unit
29: Timing generation circuit
41: Pixel circuit
51: Comparison circuit
52: Data storage unit
60: Frame
61: Differential input circuit
62: Voltage conversion circuit
63: Positive feedback circuit
71: Latch control circuit
72: Latch storage unit
121: Photodiode
122: Discharge transistor
123: Transfer transistor
124: Reset transistor
241D: D-phase latch control unit
241P: P-phase latch control unit
242: Bit storage unit
242D: D-phase bit storage unit
242P: P-phase bit storage unit
243: Switch
244: Latch circuit
245: Pre-charge circuit
281: Inverter
282: AND gate
283: NOR circuit
284: NAND gate
341: Shift register
342: Clock supply circuit
371: Bidirectional buffer circuit
381: Buffer circuit
382: Inverter circuit
561D: AND circuit
561P: AND circuit

1. An imaging device comprising:
a pixel array unit that has a plurality of pixels;
a time code generation unit that generates a time code changing with time;
a reference signal generation unit that generates a reference signal that has a voltage level changing with time; and
an AD converter that achieves analog-digital conversion of a pixel signal by comparison between the pixel signal and the reference signal, wherein
the AD converter has a storage unit that stores the time code including a plurality of bits and corresponding to the pixel signal by comparison between the pixel signal and the reference signal,
the storage unit has, for each of the plurality of bits,
a first inverter that switches whether or not to perform an inversion output operation of an input signal according to a first control signal, and
a second inverter that has an input node connected to an output node of the first inverter and an output node connected to an input node of the first inverter, and
the first inverter has
a first transistor that is of P-type and has a source connected to a first reference voltage node and a gate connected to the output node of the second inverter,
a second transistor that is of P-type and has a source connected to a drain of the first transistor, a gate to which an inversion signal of the first control signal is input, and a drain connected to the output node of the first inverter,
a third transistor that is of N-type and has a drain connected to the drain of the second transistor and the output node of the first inverter and a gate to which the first control signal is input, and
a fourth transistor that is of N-type and has a drain connected to a source of the third transistor, a source connected to a second reference voltage node, and a gate connected to the output node of the second inverter.

2. The imaging device according to claim 1, wherein
the second inverter has
a fifth transistor that is of P-type and has a source connected to the first reference voltage node, a drain connected to the gate of the first transistor and the gate of the fourth transistor, and a gate connected to the output node of the first inverter, and
a sixth transistor that is of N-type and has a drain connected to the drain of the fifth transistor, a source connected to the second reference voltage node, and a gate connected to the output node of the first inverter.

3. The imaging device according to claim 2, wherein
bit data corresponding to a time code associated with the pixel signal is written to the storage unit via one digital signal bit line for each bit, and the bit data that corresponds to the time code and that is read from the storage unit is output to the one digital signal bit line.

4. The imaging device according to claim 3, wherein
the storage unit has, for each of the plurality of bits, a transfer gate connected between the output node of the first inverter and the digital signal bit line,
the transfer gate has a seventh transistor of N-type and an eighth transistor of P-type, the seventh transistor and the eighth transistor being connected in parallel between the output node of the first inverter and the digital signal bit line, and
a second control signal for controlling opening and closing of the transfer gate is input to each of gates of the seventh transistor and the eighth transistor.

5. The imaging device according to claim 4, wherein
the time code associated with the pixel signal is stored in the storage unit for each bit via the digital signal bit line and the transfer gate, and
the time code stored in the storage unit is read via the digital signal bit line and the transfer gate.

6. The imaging device according to claim 4, wherein
the storage unit has
a first storage unit that stores the time code associated with the pixel signal at a reset level, and
a second storage unit that stores the time codes associated with the pixel signals corresponding to intensity levels of each light entering the plurality of pixels, and
the first storage unit and the second storage unit share the digital signal bit line for each of the plurality of bits.

7. The imaging device according to claim 6, wherein
each of the first storage unit and the second storage unit has the first inverter, the second inverter, and the transfer gate, and
the same digital signal bit line is connected to the respective transfer gates of the first storage unit and the second storage unit included in the same bit.

8. The imaging device according to claim 4, wherein
a plurality of the storage units corresponding to a plurality of adjoining pixels read and write the bit data corresponding to the time code via the same digital signal bit line for each bit.

9. The imaging device according to claim 4, further comprising:
a first diffusion layer and a second diffusion layer each extending in a first direction and disposed away from each other in a second direction crossing the first direction;
a first gate layer, a second gate layer, a third gate layer, a fourth gate layer, a fifth gate layer, and a sixth gate layer disposed on the first diffusion layer and the second diffusion layer, each extending in the second direction, and disposed away from each other in the first direction;
a first wiring layer disposed on the first gate layer via a first contact;
a second wiring layer disposed on the second gate layer via a second contact;
a third wiring layer disposed on the third gate layer via a third contact;
a fourth wiring layer disposed on the fourth gate layer via a fourth contact;
a fifth wiring layer disposed on the fifth gate layer via a fifth contact;
a sixth wiring layer disposed on the sixth gate layer via a sixth contact;
a first diffusion region, a second diffusion region, a third diffusion region, a fourth diffusion region, and a fifth diffusion region disposed away from each other inside the first diffusion layer;
a sixth diffusion region, a seventh diffusion region, an eighth diffusion region, a ninth diffusion region, and a tenth diffusion region disposed away from each other inside the second diffusion layer;
a seventh wiring layer disposed on the second diffusion region via a seventh contact and conductively connected to the first reference voltage node;
an eighth wiring layer disposed on the seventh diffusion region via an eighth contact and conductively connected to the second reference voltage node;
a ninth wiring layer disposed on the first diffusion region via a ninth contact and disposed on the sixth diffusion region via a tenth contact;
a tenth wiring layer disposed on the fourth diffusion region via an eleventh contact and disposed on the ninth diffusion region via a twelfth contact; and
an eleventh wiring layer disposed on the fifth diffusion region via a thirteenth contact and disposed on the tenth diffusion region via a fourteenth contact,
wherein
the first gate layer is connected to the gate of the fifth transistor and the gate of the sixth transistor,
the second gate layer is connected to the gate of the first transistor and the gate of the fourth transistor,
the third gate layer is connected to the gate of the third transistor,
the fourth gate layer is connected to the gate of the second transistor,
the fifth gate layer is connected to the gate of the seventh transistor,
the sixth gate layer is connected to the gate of the eighth transistor,
the first diffusion region includes a source region of the fifth transistor,
the second diffusion region includes a drain region of the fifth transistor and a source region of the first transistor,
the third diffusion region includes a drain region of the first transistor and a source region of the second transistor,
the fourth diffusion region includes a drain region of the second transistor and a drain region of the eighth transistor,
the fifth diffusion region includes a source region of the eighth transistor,
the sixth diffusion region includes a drain region of the sixth transistor,
the seventh diffusion region includes a source region of the sixth transistor and a source region of the fourth transistor,
the eighth diffusion region includes a drain region of the fourth transistor and a source region of the third transistor,
the ninth diffusion region includes a drain region of the third transistor and a source region of the seventh transistor, and
the tenth diffusion region includes a drain region of the seventh transistor.

10. The imaging device according to claim 9, wherein
each of the first transistor, the second transistor, the fifth transistor, and the eighth transistor disposed on the first diffusion layer is of a first conductivity type, and
each of the third transistor, the fourth transistor, the sixth transistor, and the seventh transistor disposed on the second diffusion layer is of a second conductivity type.

11. The imaging device according to claim 9, wherein
four diffusion layers that include the first diffusion layer and the second diffusion layer are so disposed as to extend in the first direction,
the four diffusion layers are disposed away from each other in the second direction, and
transistor groups are disposed on the four diffusion layers in an order of a first conductivity type, a second conductivity type, the second conductivity type, and the first conductivity type in the second direction.

12. The imaging device according to claim 9, wherein
the third gate layer is a partial conductive layer that is one of two divisions of a first conductive layer extending in the second direction, and
the fourth gate layer is the other partial conductive layer of the two divisions.

13. The imaging device according to claim 9, wherein
the fifth gate layer is a partial conductive layer that is one of two divisions of a second conductive layer CL2 extending in the second direction, and
the sixth gate layer is the other partial conductive layer of the two divisions.

14. The imaging device according to claim 9, wherein
the first to sixth gate layers, the first to eleventh wiring layers, and the first to tenth diffusion regions of two bits disposed adjacently to each other in the first direction within the storage unit are line-symmetrically disposed with respect to a boundary line extending in the second direction.

15. The imaging device according to claim 9, wherein
the first to sixth gate layers, the first to eleventh wiring layers, and the first to tenth diffusion regions of two bits disposed adjacently to each other in the second direction within the storage unit are line-symmetrically disposed with respect to a boundary line extending in the first direction.

16. The imaging device according to claim 9, wherein
the first to sixth gate layers, the first to eleventh wiring layers, and the first to tenth diffusion regions of two bits disposed adjacently to each other in each of the first direction and the second direction within the storage unit are line-symmetrically disposed with respect to each of a first boundary line extending in the first direction and a second boundary line extending in the second direction.

17. The imaging device according to claim 4, further comprising:
a pre-charge circuit that pre-charges the digital signal bit line to a predetermined potential before writing of the time code to the storage unit.

18. The imaging device according to claim 4, wherein
the digital signal bit line performs writing of the time code to the storage unit and reading of the time code from the storage unit by time division.

19. A semiconductor memory comprising:
a storage unit that includes a plurality of bits, wherein
the storage unit has, for each of the plurality of bits,
a first inverter that switches whether or not to perform an inversion output operation of an input signal according to a first control signal,
a second inverter connected to an input node and an output node of the first inverter, and
a transfer gate connected between the output node of the first inverter and a digital signal bit line,
the first inverter has
a first transistor that is of P-type and has a source connected to a first reference voltage node and a gate connected to an output node of the second inverter,
a second transistor that is of P-type and has a source connected to a drain of the first transistor, a gate to which an inversion signal of the first control signal is input, and a drain connected to an output node,
a third transistor that is of N-type and has a drain connected to the drain of the second transistor and the output node and a gate to which the first control signal is input, and
a fourth transistor that is of N-type and has a drain connected to a source of the third transistor, a source connected to a second reference voltage node, and a gate connected to the output node of the second inverter,
the second inverter has
a fifth transistor that has a source connected to the first reference voltage node, a drain connected to the gate of the first transistor and the gate of the fourth transistor, and a gate connected to the drain of the second transistor and the drain of the third transistor, and
a sixth transistor that has a drain connected to the gate of the first transistor and the gate of the fourth transistor, a source connected to the second reference voltage node, and a gate connected to the drain of the second transistor and the drain of the third transistor,
the transfer gate has a seventh transistor of N-type and an eighth transistor of P-type connected in parallel between the output node of the first inverter and the digital signal bit line, and
a second control signal for controlling opening and closing of the transfer gate is input to each of gates of the seventh transistor and the eighth transistor.
